(19) United States
(12) Patent Application Publication
(10) Pub. No.: US 2025/0051911 A1
(43) Pub. Date: Feb. 13, 2025

(54) FILM FORMING METHOD

(71) Applicants: AIR WATER INC., Osaka-shi, Osaka (JP); KOKUSAI ELECTRIC CORPORATION, Tokyo (JP)

(72) Inventors: Fumio KAWASAKI, Matsumoto-shi, Nagano (JP); Keisuke NAGATA, Matsumoto-shi, Nagano (JP); Yasunori OTSUKA, Matsumoto-shi, Nagano (JP); Kimihiko NAKATANI, Toyama-shi, Toyama (JP); Yoshitomo HASHIMOTO, Toyama-shi, Toyama (JP); Yoshiro HIROSE, Toyama-shi, Toyama (JP)

(73) Assignees: AIR WATER INC., Osaka-shi, Osaka (JP); KOKUSAI ELECTRIC CORPORATION, Tokyo (JP)

(21) Appl. No.: 18/720,116

(22) PCT Filed: Dec. 14, 2022
(86) PCT No.: PCT/JP2022/046105

§ 371 Date: Jun. 14, 2024

(30) Foreign Application Priority Data
Dec. 17, 2021 (JP) 2021-205298

(51) Int. Cl. C23C 16/455; C23C 16/40; C23C 16/44; H01L 21/02

(52) U.S. Cl. CPC C23C 16/45534; C23C 16/402; C23C 16/4408; C23C 16/45553; H01L 21/02164; H01L 21/02208

(57) ABSTRACT

A film forming method for forming a film on a workpiece is disclosed including: supplying a source gas into a treatment container provided with the workpiece to adsorb the source gas on the workpiece, and then purging an inside of the treatment container with a first purge gas, and supplying a reaction gas into the treatment container after the source gas supply process to oxidize the source gas adsorbed on the workpiece, and then purging the inside of the treatment container with a second purge gas, in which for example, the source gas and a first catalyst gas are supplied to the treatment container in the source gas supply process, the reaction gas and a second catalyst gas are supplied to the treatment container in the reaction gas supply process, and the same or different non-aromatic amine gas are used as the first catalyst gas and the second catalyst gas.

### TECHNICAL FIELD

The present invention relates to a film forming method, and more particularly to a film forming method capable of forming a film such as a SiO₂ film on a workpiece.

### BACKGROUND ART

In recent years, in fields such as electronics fields including semiconductor and liquid crystal fields, and organic chemicals such as pharmaceuticals and foodstuffs, there is an increasing need for lowering the film formation temperature in, for example, a film forming method on a substrate or the like made of a material having a low heat-resistant temperature, and a film forming method capable of reducing thermal effect and retaining material characteristics. Here, examples of the method that enables film formation at a low temperature include plasma chemical vapor deposition (CVD), plasma atomic layer deposition (ALD), vacuum deposition, sputtering, plating, thermal CVD, thermal ALD, and the like.

Among these film forming methods, in the film forming method using plasma, a reaction equivalent to that in a high-temperature region can be achieved by using plasma energy. However, this film forming method has a problem that plasma active species cause damage to the thin film. In addition, since there may be an unexpected effect on a film forming device, when a film forming method using plasma is adopted, it is necessary to confirm in advance what kind of effect occurs.

In addition, in the case of vacuum deposition and sputtering, it is difficult to form a film on a fine pattern-formed surface on a substrate. Therefore, these film forming methods cannot be adopted for manufacturing a highly integrated semiconductor device or the like.

Therefore, it is conceivable to adopt thermal ALD capable of suppressing damage and forming a thin film having favorable film quality and having high film formation controllability. However, in the case of this film forming method, there is a problem that the activation energy required for the reaction of a chemical species for obtaining a target compound is often not exceeded in a low-temperature region. Accordingly, it is necessary to promote a chemical reaction by adding energy other than thermal energy (for example, energy such as plasma and ultraviolet (UV)) to promote the film formation but the plasma causes damage to the thin film as described above. In addition, since UV also causes damage in the same manner, there is a problem that thermal ALD is unsuitable for film formation in a low-temperature region.

For such a problem, for example, Patent Document 1 discloses a technique of forming a film at a low temperature using thermal ALD. More specifically, it is described that a SiO₂ film can be formed on an organic substrate at a low temperature by using NHS as a catalyst and an alkoxysilane such as tetramethoxysilane (TMOS) or triethoxysilane (TEOS) as a source gas under atmospheric pressure. However, in the film forming method disclosed in Patent Document 1, the supply time of alkoxysilane as a source gas needs to be long, for example, 3 minutes to 4 minutes per cycle. Therefore, the film forming method of Patent Document 1 has a problem of low productivity.

In addition, Patent Document 2 describes that a SiO₂ film can be formed on a substrate at a low temperature by using pyridine as a catalyst and hexachlorodisilane (HCDS) having high reaction activity as a source gas. However, in the film forming method disclosed in Patent Document 2, when the film formation temperature is 67° C. or lower, there is a problem that a salt is generated in a reactor due to chlorine atoms contained in the HCDS. In addition, when a peripheral metal film is formed, there is also a problem that the metal film is corroded and damaged.

Patent Document 3 describes that a SiO₂ film can be formed on a substrate at a low temperature by using a pyrimidine as a catalyst ligand and a precursor containing silicon and oxygen. However, Patent Document 3 describes that a SiO₂ film grows to a film thickness of 1 Å to 6 Å per cycle. This means that the film formation of the SiO₂ film per cycle varies in a film thickness range of 1 Å to 6 Å. Accordingly, the film forming method disclosed in Patent Document 3 has a problem that the film thickness controllability of the SiO₂ film is poor.

Non-Patent Document 1 describes that a SiO₂ film can be formed on ZrO₂ and BaTiO₃ particles at room temperature using tetrakisethoxysilane (TEOS) as a silicon precursor, H₂O as an oxidant, and ammonia as a catalyst. However, Non-Patent Document 1 does not describe forming a SiO₂ film on a silicon substrate, and it is difficult to apply the film forming method described in Non-Patent Document 1 to a semiconductor device. In addition, the supply time of ammonia is 9,400 seconds per cycle, and the film forming method of Non-Patent Document 1 has a problem that productivity is low and is not industrially applicable.

### PRIOR ART DOCUMENTS

### Patent Documents

Patent Document 1: WO 2011/156,484 A
Patent Document 2: U.S. Pat. No. 6,992,019
Patent Document 3: U.S. Pat. No. 8,380,699

### Non-Patent Document

Non-Patent Document 1: JOURNAL OF ELECTROCHEMICAL SOCIETY, 151(8)G528-G535, 2004

### SUMMARY OF THE INVENTION

### Problems to be Solved by the Invention

The present invention has been made in view of the above problems, and an object thereof is to provide a film forming method capable of forming a high-density film on a workpiece at a favorable film formation rate at a low temperature and applicable to industrial production.

### Solutions to the Problems

The conventional problems are solved by the invention described below.

That is, in order to solve the above problems, a film forming method according to the present invention is a film forming method for forming a film on a workpiece, the method comprising:
a process (A) of providing the workpiece in a treatment container;
a source gas supply process (B) of supplying a source gas into the treatment container to adsorb the source gas onto the workpiece, and then purging an inside of the treatment container with a first purge gas; and
a reaction gas supply process (C) of supplying a reaction gas into the treatment container after the source gas supply process (B) to oxidize the source gas adsorbed on the workpiece, and then purging the inside of the treatment container with a second purge gas,
wherein the supply of the source gas in the source gas supply process (B) is one of:
   a process (b1) of supplying a first catalyst gas into the treatment container together with the source gas;
   a process (b2) of supplying a first catalyst gas into the treatment container, then performing purging with a third purge gas, and then supplying the source gas; or
   a process (b3) of supplying only the source gas into the treatment container,
the supply of the reaction gas in the reaction gas supply process (C) is one of:
   a process (c1) of supplying a second catalyst gas into the treatment container together with the reaction gas:
   a process (c2) of supplying a second catalyst gas into the treatment container before supplying the reaction gas, and then performing purging with a fourth purge gas; or
   a process (c3) of supplying only the reaction gas into the treatment container,
the method does not comprise the reaction gas supply process (C) being the process (c3) when the source gas supply process (B) is the process (b3), and the first catalyst gas and the second catalyst gas are the same or different types of non-aromatic amine gas.

In the above configuration, an acid dissociation constant pKa of the non-aromatic amine gas at 25° C. is preferably in a range of 9.5 or more and 14 or less.

In the above configuration, the non-aromatic amine gas may be at least one type selected from a group consisting of a pyrrolidine gas, a piperidine gas, a tetramethylguanidine gas, a 1-methylpiperidine gas, and a gas of a derivative thereof.

In the above configuration, the source gas is preferably a group 4 element gas of the periodic table having no halogen ligand and/or a silicon gas having no halogen ligand.

In the above configuration, the source gas is preferably represented by a general formula Am-M-B(4−m)(where A and B are each independently any one type selected from a group consisting of an R¹O group, an R²R³N group, a CpR⁴ group, a C_{q}H_{2q}N group (q=4 or 5), and a hydrogen atom. In addition, R¹, R², R³, and R⁴ are each independently a CᵣH₂ᵣ₊₁ group (r≥0). M is Ti, Zr, Hf, or Si. Cp is a cyclopentadienyl ligand. 0≤m≤4).

In the above configuration, the source gas is preferably at least one type of gas selected from a group consisting of Si(OMe)₄, Si(NMe₂)(OMe)₃, Si(NMe₂)₂(OMe)₂, Si(NMe₂)(OMe), Si(NMe₂)(OEt)₃, Si(NMe₂)₂(OEt)₂, Si(NMe₂)₃(OEt), Si(NEt₂)(OMe)₃, Si(NEt₂)(OEt)₃, SiH(NMe₂)₃, SiH₂(NEt₂), SiH₂(NHt-Bu)₂, Si(pyrrolidine)(OMe)₃, Si(pyrrolidine)₂(OMe)₂, and Si(pyrrolidine)₃(OMe).

In the above configuration, the reaction gas is preferably an oxidant gas having an oxygen atom.

In the above configuration, the oxidant gas is preferably at least one type of gas selected from a group consisting of water, hydrogen peroxide water, formic acid, and aldehyde.

In the above configuration, it is preferable that the supply of the source gas and/or the first catalyst gas in the source gas supply process is performed such that a pressure in the treatment container is in a range of 13 Pa or more and 40000 Pa or less, and the supply of the reaction gas and/or the second catalyst gas in the reaction gas supply process is performed such that the pressure in the treatment container is in a range of 13 Pa or more and 40000 Pa or less.

In the above configuration, a temperature in the treatment container in the source gas supply process and/or the reaction gas supply process is preferably 200° C. or lower.

### Effects of the Invention

The present invention can provide a film forming method capable of forming a film having favorable film quality on a workpiece at a low temperature and applicable to industrial production.

### BRIEF DESCRIPTION OF THE DRAWINGS

FIG. 1 is a schematic system diagram illustrating a film forming device according to an embodiment of the present invention.

FIG. 2 is a flowchart for describing a film forming method according to the present embodiment.

FIG. 3 is a schematic diagram illustrating a state in which a source gas is adsorbed on a substrate when the source gas and a first catalyst gas are simultaneously supplied in the present embodiment.

FIG. 4 is a schematic diagram illustrating a state in which a source gas is adsorbed on a substrate when only the source gas is supplied in the present embodiment.

FIG. 5 is a schematic diagram illustrating a state in which an OH group is introduced into an adsorbed molecule adsorbed on a substrate surface when a reaction gas and a second catalyst gas are simultaneously supplied in the present embodiment.

FIG. 6 is a schematic diagram illustrating a state in which an OH group is introduced into an adsorbed molecule adsorbed on a substrate surface when only a reaction gas is supplied in the present embodiment.

FIG. 7 is a diagram illustrating a film formation sequence for a SiO₂ film in Present Example I.

FIG. 8 is a diagram illustrating a film formation sequence for a SiO₂ film in Present Example 2.

FIG. 9 is a diagram illustrating a film formation sequence for a SiO₂ film in Present Example 3.

FIG. 10 is a diagram illustrating a film formation sequence for a SiO₂ film in Present Example 4.

FIG. 11 is a graph illustrating a correlation between the number of cycles and the film thickness of a SiO₂ film in a case where a TMOS gas is used as a source gas.

FIG. 12 is a graph illustrating a relationship between the temperature in a treatment container and the film formation rate of a SiO₂ film in various film forming methods.

FIG. 13 is a graph illustrating a correlation between the number of cycles and the film thickness of a SiO₂ film in a case where a 3DMAS gas is used as a source gas.

FIG. 14 is a graph illustrating a relationship between the temperature in a treatment container and the film formation rate of a SiO₂ film in various film forming methods.

FIG. 15 is a graph illustrating a relationship between the pressure in a treatment container and the film formation rate of a SiO₂ film in various film forming methods.

FIG. 16 is a graph illustrating a relationship between the pressure in a treatment container and the film formation rate of a SiO₂ film in various film forming methods.

FIG. 17 is a diagram illustrating a film formation sequence for a SiO₂ film in Present Example 37.

FIG. 18 is a graph illustrating a relationship between the supply time (pulse time) of a reaction gas and the film formation rate of a SiO₂ film.

FIG. 19 is a schematic system diagram illustrating a film forming device according to a comparative example.

### EMBODIMENT OF THE INVENTION

### (Film Forming Device)

A film forming device according to an embodiment of the present invention will be described below. The film firming device according to the present embodiment can be used, for example, in a substrate treatment process that is one process of a manufacturing process for a semiconductor manufacturing device.

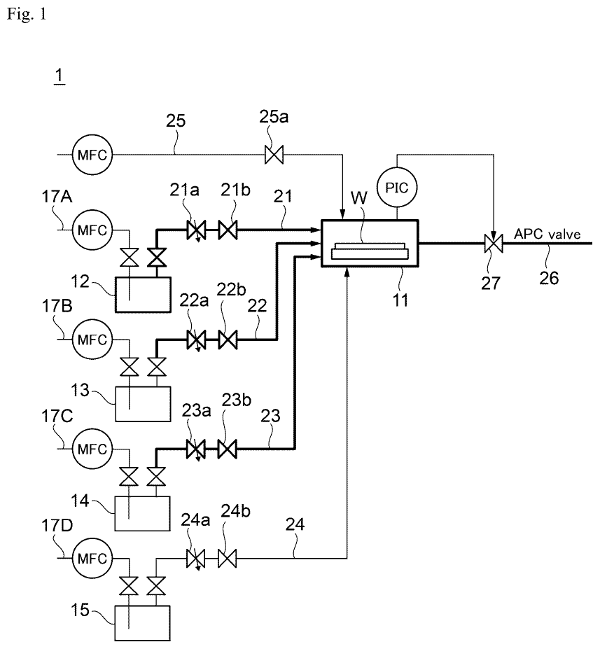

First, a configuration of the film forming device according to the present embodiment will be described with reference to FIG. 1. FIG. 1 is a schematic system diagram illustrating a film forming device according to the present embodiment.

As shown in FIG. 1, a film forming device 1 at least includes a treatment container 11 that houses a substrate W as a workpiece, a source gas supply portion 12 that supplies a source gas, a first catalyst gas supply portion 13 that supplies a first catalyst gas, a second catalyst gas supply portion 14 that supplies a second catalyst gas, a reaction gas supply portion 15 that supplies a reaction gas, a purge gas supply path 25 for supplying a purge gas, and a discharge path 26 for discharging an atmosphere in the treatment container 11.

The treatment container 11 has a sealed structure in which the inside thereof can be shielded from the outside air. In addition, the treatment container 11 is configured to be able to house the substrate W in a horizontal orientation by a boat or the like. The treatment container 11 may include a heating mechanism capable of heating the substrate W housed therein to a predetermined temperature. The heating mechanism is not particularly limited, and a known hearing mechanism such as a heater can be adopted,

The source gas supply portion 12 has a function of supplying the source gas to the treatment container 11. The source gas supply portion 12 stores a source in the form of a liquid. In addition, the source gas supply portion 12 is provided with a carrier gas supply path 17A for introducing a carrier gas. The flow rate of the carrier gas supplied from the carrier gas supply path 17A can be controlled by a mass flow controller (MFC). Note that details of the source gas and the carrier gas will be described below.

A source gas supply path 21 is provided between the source gas supply portion 12 and the treatment container 11. As a result, the source gas obtained by vaporizing the source in the form of a liquid stored in the source gas supply portion 12 can be supplied to the treatment container 11. In addition, in the source gas supply path 21, a needle valve 21a and an opening/closing valve 21b are sequentially provided from the upstream side.

The first catalyst gas supply portion 13 has a function of supplying the first catalyst gas to the treatment container 11. The first catalyst gas supply portion 13 stores, for example, a first catalyst in the form of a liquid. In addition, the first catalyst gas supply portion 13 is provided with a carrier gas supply path 17B for introducing a carrier gas. The flow rate of the carrier gas supplied from the carrier gas supply path 17B can be controlled by a MFC. Note that details of the first catalyst gas and the carrier gas will be described below.

A first catalyst gas supply path 22 is provided between the first catalyst gas supply portion 13 and the treatment container 11. As a result, the first catalyst gas obtained by vaporizing the first catalyst in the form of a liquid stored in the first catalyst gas supply portion 13 can be supplied to the treatment container 11. In addition, in the first catalyst gas supply path 22, a needle valve 22a and an opening/closing valve 22b are sequentially provided from the upstream side.

The second catalyst gas supply portion 14 has a function of supplying the second catalyst gas to the treatment container 11. The second catalyst gas supply portion 14 stores, for example, a second catalyst in the form of a liquid. In addition, the second catalyst gas supply portion 14 is provided with a carrier gas supply path 17C for introducing a carrier gas. The flow rate of the carrier gas supplied from the carrier gas supply path 17C can be controlled by a MFC. Note that details of the second catalyst gas and the carrier gas will be described below.

A second catalyst gas supply path 23 is provided between the second catalyst gas supply portion 14 and the treatment container 11. As a result, the second catalyst gas obtained by vaporizing the second catalyst in the form of a liquid stored in the second catalyst gas supply portion 14 can be supplied to the treatment container 11. In addition, in the second catalyst gas supply path 23, a needle valve 23a and an opening/closing valve 23b are sequentially provided from the upstream side.

The reaction gas supply portion 15 has a function of supplying the reaction gas to the treatment container 11. The reaction gas supply portion 15 stores an oxidant in the form of a liquid. In addition, the reaction gas supply portion 15 is provided with a carrier gas supply path 17D for introducing a carrier gas. The flow rate of the carrier gas supplied from the carrier gas supply path 17D can be controlled by a MFC. Note that details of the reaction gas and the carrier gas will be described below.

A reaction gas supply path 24 is provided between the reaction gas supply portion 15 and the treatment container 11. As a result, the reaction gas obtained by vaporizing the oxidant in the form of a liquid stored in the reaction gas supply portion 15 can be supplied to the treatment container 11. In addition, in the reaction gas supply path 24, a needle valve 24a and an opening/closing valve 24b are sequentially provided from the upstream side.

The needle valves 21a, 22a, 23a, and 24a adjust the flow rates of the gases flowing through the respective supply paths. In addition, each of the opening/closing valves 21b, 22b, 23b, and 24b controls the supply or stop of the gas flowing through each supply path by performing opening/closing control.

The purge gas supply path 25 has a function of supplying the purge gas into the treatment container 11. The purge gas supply path 25 is connected to the treatment container 11, and is provided with an opening/closing valve 25a. The opening/closing of the opening/closing valve 25a is controlled to control the supply or stop of the purge gas flowing through the purge gas supply path 25. Note that details of the purge gas will be described below.

The discharge path 26 is connected to the treatment container 11 and has a function of discharging the atmosphere in the treatment container 11. A pressure sensor (not shown) as a pressure detection portion that detects the pressure in the treatment container 11, an automatic pressure control (APC) valve 27 as a pressure control portion that controls the pressure in the treatment container 11, and a vacuum pump (not shown) as a vacuum exhaust device are connected to the discharge path 26 in order from the upstream side. The opening/closing control of the APC valve 27 is performed by PID control based on the measurement of the pressure sensor in a state where the vacuum pump is activated. As a result, the pressure in the treatment container 11 can be arbitrarily adjusted,

Note that the exhaust gas discharged from the discharge path 26 may include a toxic gas, a combustible gas, and the like. Therefore, a water washing scrubber, a sulfuric acid scrubber, a caustic scrubber, a dry scrubbing device, or the like (none of them is shown) may be provided in the discharge path 26 to detoxify the exhaust gas so that the exhaust gas can be released to the atmosphere.

### (Film Forming Method)

Next, a film forming method according to the present embodiment using the film forming device 1 will be described.

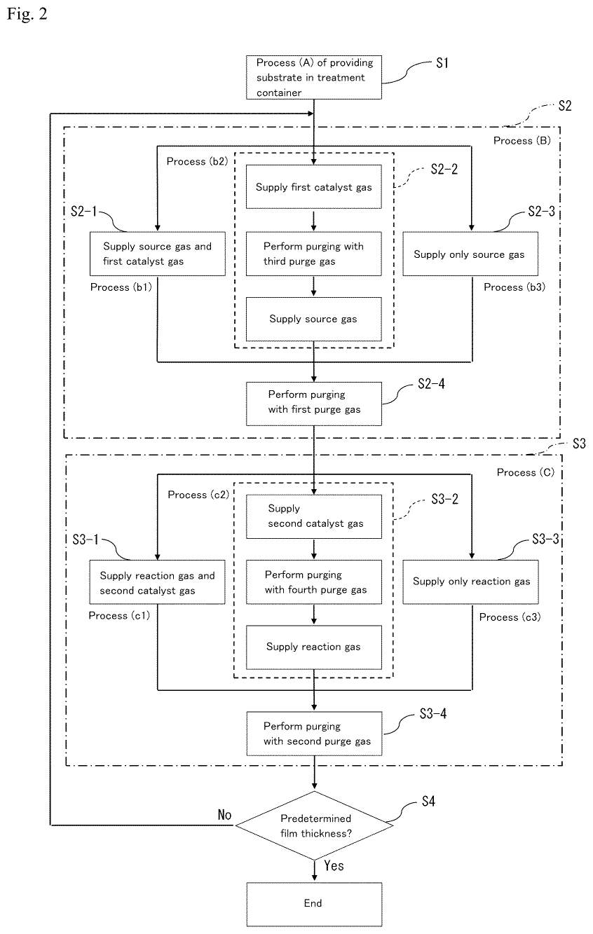

The film forming method according to the present embodiment enables formation of a film on a workpiece. More specifically, as shown in FIG. 2, the film forming method of the present embodiment includes at least a process (A) of providing the substrate W, which is a workpiece, in the treatment container 11 (S1), a source gas supply process (B) of supplying the source gas into the treatment container 11 to adsorb the source gas onto the substrate W, and then purging the inside of the treatment container 11 with a first purge gas (S2), and a reaction gas supply process (C) of supplying the reaction gas into the treatment container 11 after the source gas supply process (B) to oxidize the source gas adsorbed onto the substrate W, and then purging the inside of the treatment container 11 with a second purge gas (S3). Hereinafter, each process will be described in detail. Note that FIG. 2 is a flowchart for describing the film forming method of the present embodiment.

### [Process (A) of Providing Workpiece in Treatment Container]

First, the substrate W, which is a workpiece, is placed in the treatment container 11 in the state of a horizontal orientation such that a treatment surface (front surface) of the substrate W faces upward. Here, in the present specification, words indicating directions such as upward, downward, and horizontal mean directions based on the treatment surface (front surface) of the substrate W.

The present process (A) can include a process of adjusting the pressure and the temperature in the treatment container 11 in which the substrate W is housed. The pressure in the treatment container 11 can be adjusted by performing evacuation (decompression exhaust) using a vacuum pump so as to obtain a desired pressure (vacuum degree). At this time, the pressure in the treatment container 11 is measured by the pressure sensor, and the APC valve 27 is PID-controlled based on the measurement value of the pressure sensor. The pressure in the treatment container 11 can be continuously adjusted by the vacuum pump or the like until the film formation is ended, in addition, the temperature in the treatment container 11 can be adjusted by heating by the above-described heating mechanism so as to have a desired film formation temperature. The temperature in the treatment container 11 by the heating mechanism can be continuously adjusted until the film formation treatment is ended.

### [Source Gas Supply Process (B)]

The source gas supply process (B) of the present embodiment is a process of supplying the source gas into the treatment container 11 to (chemically) adsorb the source gas onto the substrate W, and then purging the inside of the treatment container 11 with the first purge gas (S2).

In the source gas supply process (B), as shown in FIG. 2, the adsorption of the source gas to the substrate W is any of a case of a process (b1) of supplying the first catalyst gas into the treatment container 11 together with the source gas (S2-1), a case of a process (b2) of supplying the first catalyst gas into the treatment container 11 before supplying the source gas, and then performing purging with a third purge gas (S2-2), and a case of a process (b3) of supplying only the source gas into the treatment container 11 (S2-3). Hereinafter, the process (b1), the process (b2), and the process (b3), and the purge process with the first purge gas will be sequentially described.

(1) Process (b1) of Supplying the First Catalyst Gas Together with the Source Gas

In the present process (b1), the source gas and the first catalyst gas are simultaneously supplied to the treatment container 11 (S2-1).

When the source gas is supplied to the treatment container 11, the carrier gas is supplied from the carrier gas supply path 17A to the source gas supply portion 12. The carrier gas is not particularly limited, and examples thereof include inert gases such as nitrogen gas, argon gas, and helium gas. These inert gases can be used alone or in combination. In addition, the flow rate of the supply of the carrier gas is controlled by the MFC. Further, the carrier gas that does not contain moisture as much as possible is preferable.

When the carrier gas is supplied to the source gas supply portion 12, the carrier gas is discharged from the source gas supply path 21 together with the source gas obtained by vaporizing the source stored in a liquid state in the source gas supply portion 12. In the source gas supply path 21, the opening/closing valve 21b is in an opened state by the opening/closing control, and the mixture gas including the carrier gas and the source gas is supplied into the treatment container 11 while the flow rate of the mixture gas is adjusted by the needle valve 21a.

As the source gas, a group 4 element gas of the periodic table having no halogen ligand and/or a silicon gas having no halogen ligand are preferable.

In addition, the source gas can be represented by a general formula Aₘ-M-B₍₄₋ₘ₎ (where A and B are each independently any one type selected from a group consisting of an R¹O group, an R²R³N group, a CpR⁴ group, a C_{q}H_{2q}N group (q=4 or 5), and a hydrogen atom (note that Cp means a cyclopentadienyl ligand). In addition. R¹, R², R³ and R⁴ are each independently a CᵣH₂ᵣ₊₁ group (r≥0). M is Ti, Zr, Hf, or Si. 0≤m≤4).

Further, among the source gases represented by the general formula, the source gas is preferably at least one type of gas selected from a group consisting of Si(OMe)₄, Si(NMe₂)(OMe)₃, Si(NMe₂)₂(OMe)₂, Si(NMe₂)₃(OMe), Si(NMe₂)(OEt)₃, Si(NMe₂)₂(OEt)₂, Si(NMe₂)₂(MEt), Si(NEt₂)(OMe)₃, Si(NEt₂)(QEt)₃, SiH(NMe₂)₃, SiH₂(NEt₂)₂, SiH₂(NHt-Bu)₂, Si(pyrrolidine)OMe)₃, Si(pyrrolidine)₂(OMe)₂, and Si(pyrrolidine)₃(OMe)(note that Me represents a methyl group, Et represents an ethyl group, and t-Bu represents a tertiary butyl group). Note that the source gas that does not contain moisture as much as possible is preferable. In addition, the exemplified source gas can be used in any combination with any of the above-described exemplified carrier gases.

The supply flow rate of the mixture gas including the source gas and the carrier gas (supply flow rate of source gas in the case of only source gas) is preferably in a range of 1 sccm or more and 5000 sccm or less, more preferably in a range of 100 sccm or more and 3000 sccm or less, and particularly preferably in a range of 200 sccm or more and 2000 sccm or less. By setting the supply flow rate of the mixture gas (or source gas) to 1 sccm or more, the reaction rate (film formation rate) of the source gas can be favorably maintained, and the adsorption of the source gas onto the substrate W can be prevented from becoming insufficient. On the other hand, by setting the supply flow rate of the mixture gas (or source gas) to 5000 sccm or less, the gas consumption amount can be reduced. The supply flow rate of the mixture gas (or source gas) can be appropriately controlled by adjusting the temperature of the source gas, the flow rate of the carrier gas, and the pressure in the source gas supply portion 12. Note that the supply flow rate of the carrier gas to be mixed with the source gas is not particularly limited, and can be appropriately set according to the supply flow rate of the mixture gas described above.

In addition, when the first catalyst gas is supplied to the treatment container 11, the carrier gas is supplied from the carrier gas supply path 178 to the first catalyst gas supply portion 13. The details of the carrier gas are as described above. In addition, the flow rate of the supply of the carrier gas is controlled by the MFC. Note that the carrier gas that does not contain moisture as much as possible is preferable,

When the carrier gas is supplied to the first catalyst gas supply portion 13, the carrier gas is discharged from the first catalyst gas supply path 22 together with the first catalyst gas obtained by vaporizing the first catalyst stored in the first catalyst gas supply portion 13. In the first catalyst gas supply path 22, the opening/closing valve 22b is in an opened state by the opening/closing control, and the mixture gas including the carrier gas and the first catalyst gas is supplied into the treatment container 11 while the flow rate of the mixture gas is adjusted by the needle valve 22a.

The first catalyst gas is preferably a non-aromatic amine gas. In the case of a non-aromatic amine gas, the film formation rate can be improved at a low temperature of 200° C. or lower. In addition, the first catalyst gas that does not contain moisture as much as possible is preferable. Note that when a gas such as of aromatic pyridine is used as the first catalyst gas, the film formation rate may be significantly reduced. In addition, when NH₃ gas is used as the first catalyst gas, it may be difficult to form a film.

As the non-aromatic amine gas, an acid dissociation constant pKa at 25° C. is preferably in a range of 9.5 or more and 14 or less, more preferably in a range of 10 or more and 14 or less, and particularly preferably in a range of 11 or more and 14 or less. When the pKa of the non-aromatic amine gas is 9.5 or more, the film formation rate can be increased, and the film formation efficiency can be improved. On the other hand, when the pKa of the non-aromatic amine gas is 14 or less, damage to the film forming device can be prevented, and hydrolysis of the catalyst itself can be prevented. For example, the pKa can be calculated from the concentration of the substance and the hydrogen ion concentration by measuring the hydrogen ion concentration using a pH meter.

Further, specific examples of the non-aromatic amine gas include pyrrolidine (acid dissociation constant pKa at 25° C.: 11.3) gas, piperidine (acid dissociation constant pKa at 25° C.: 11.1) gas, 1,1,3,3-tetramethylguanidine (acid dissociation constant pKa at 25° C.: 13.6) gas, 1-methylpiperidine (acid dissociation constant pKa at 25° C.: 10.1) gas, and gases of derivatives thereof. These non-aromatic amine gases can be used alone or as a mixture of two or more types In addition, the exemplified non-aromatic amine gas can be used in any combination with any of the above-described exemplified source gas and carrier gas.

The supply flow rate of the mixture gas including the first catalyst gas and the carrier gas (supply flow rate of first catalyst gas in the case of only first catalyst gas) is preferably in a range of 1 sccm or more and 10000 sccm or less, more preferably in a range of 100 sccm or more and 5000 sccm or less, and particularly preferably in a range of 200 sccm or more and 2000 sccm or less. By setting the supply flow rate of the mixture gas (or first catalyst gas) to 1 sccm or more, the reaction rate (film formation rate) of the source gas can be favorably maintained, and the adsorption of the source gas onto the substrate W can be prevented from becoming insufficient. On the other hand, by setting the supply flow rate of the mixture gas (or first catalyst gas) to 10000 sccm or less, the consumption amount can be reduced. The supply flow rate of the mixture gas (or first catalyst gas) can be appropriately controlled by adjusting the temperature of the first catalyst gas, the flow rate of the carrier gas, and the pressure in the first catalyst gas supply portion 13. Note that the supply flow rate of the carrier gas to be mixed with the first catalyst gas is not particularly limited, and can be appropriately set according to the supply flow rate of the mixture gas described above.

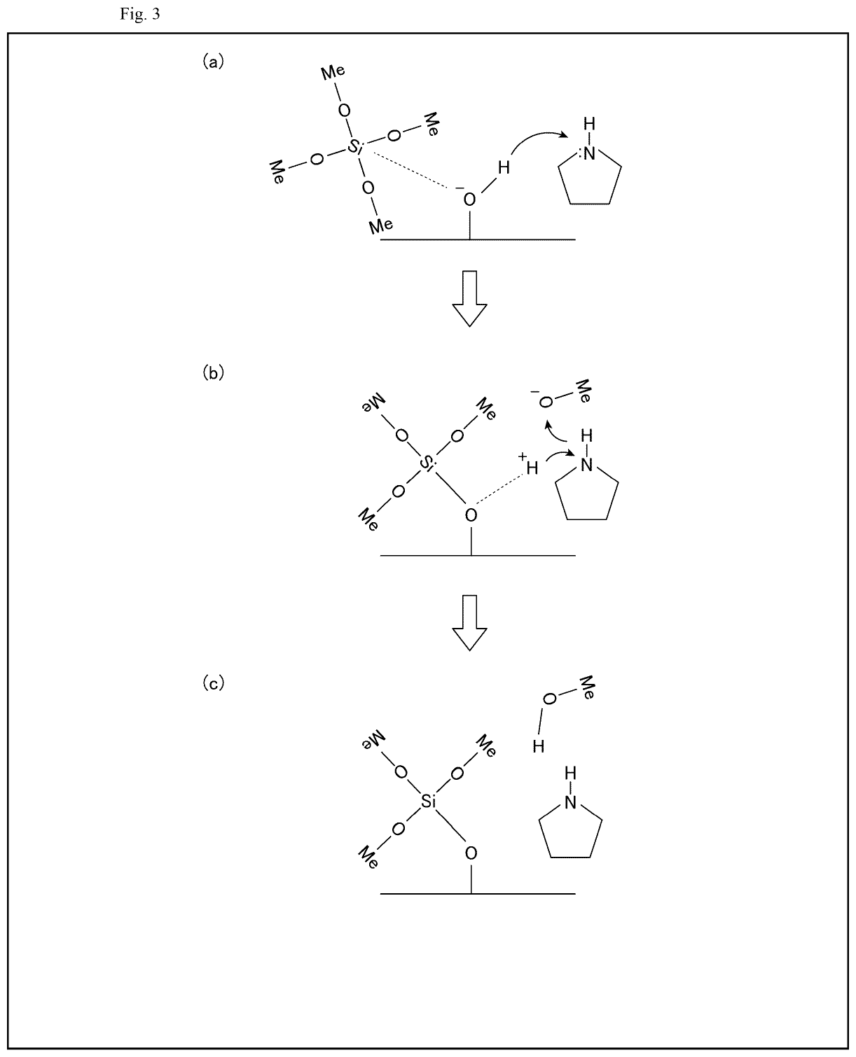

When the mixture gas including the source gas and the carrier gas and the mixture gas including the first catalyst gas and the carrier gas are supplied to the treatment container 11, the source gas is chemically adsorbed on the surface of the substrate W. In the present embodiment, by supplying the first catalyst gas into the treatment container 11 simultaneously with the source gas, the adsorption performance of the source gas to the surface of the substrate W can be improved. For example, when the source gas is Si(OMe)₄ gas and the first catalyst gas is pyrrolidine gas (see FIG. 3), when the pyrrolidine gas comes into contact with the surface of the substrate W, the lone electron pair of N atoms in the pyrrolidine abstracts H atoms from the OH group present on the surface of SiO₂ constituting the substrate W. As a result, the charge distribution is biased to negative charges in the OH group, and bonding with Si atoms in which the charge distribution is biased to positive charges is promoted in Si(OMe)₄, which is the source gas, and chemical adsorption of Si(OMe)₄ to the surface of the substrate W is promoted. In addition, at this time, a ligand MeO⁻ is desorbed from Si(OMe)₄. Further, the ligand MeO⁻ is bonded to the H atom abstracted by pyrrolidine, thereby producing MeOH as a by-product. Note that FIG. 3 is a schematic diagram illustrating a state in which the source gas is adsorbed on the substrate when the source gas and the first catalyst gas are simultaneously supplied in the present embodiment.

The temperature in the treatment container 11 at the time of supplying the source gas (or mixture gas with carrier gas) and the first catalyst gas (or mixture gas with carrier gas)(hereinafter, referred to as the “source gas and the like”) is preferably in a range of 200° C. or lower, more preferably in a range of 50° C. or higher and 150° C. or lower, and particularly preferably in a range of 80° C. or higher and 125° C. or lower. By setting the temperature in the treatment container 11 to 200° C. or lower, for example, even when the substrate W is made of a material having a low heat-resistant temperature, it is possible to form a film while avoiding the thermal effect as much as possible and maintaining the material characteristics of the substrate W.

The pressure in the treatment container 11 when the source gas and the like is supplied is preferably in a range of 1 Pa or more and 40000 Pa or less, more preferably in a range of 13 Pa or more and 13300 Pa or less, and particularly preferably in a range of 133 Pa or more and 6700 Pa or less. By setting the pressure in the treatment container 11 to 1 Pa or more, the reaction rate (film formation rate) of the source gas can be favorably maintained. On the other hand, by setting the pressure in the treatment container 11 to 40000 Pa or less, it is possible to shorten the treatment time and increase the purge efficiency. Note that the pressure in the treatment container 11 can be adjusted by controlling opening/closing of the APC valve 27 by PID control.

The supply time (pulse time) of the source gas and the like to the treatment container 11 is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the source gas and the like to 0.1 seconds or more, the reaction rate (film formation rate) of the source gas can be favorably maintained, and the adsorption of the source gas onto the substrate W can be prevented from becoming insufficient. On the other hand, by setting the supply time of the source gas and the like to 600 seconds or less, the consumption amount can be reduced, and the process time can be shortened.

The supply time of the source gas and the like can be appropriately controlled by adjusting the temperature of the source gas and the like, the flow rate of the carrier gas, the pressure in the source gas supply portion 12, and the pressure in the first catalyst gas supply portion 13. Note that the supply time of the source gas and the like means a time during which the opening/closing valve 21b and the opening/closing valve 22b are simultaneously opened.

In the present process (b1), during the supply of the source gas and the like, all of the opening/closing valve 23b of the second catalyst gas supply path 23, the opening/closing valve 24b of the reaction gas supply path 24, and the opening/closing valve 25a of the purge gas supply path 25 are in a closed state. In addition, the end of the present process (b1) is performed by bringing the opening/closing valve 21b and the opening/closing valve 22b into a closed state by the opening/closing control and stopping the supply of the mixture gas of the source gas and the carrier gas and the mixture gas of the first catalyst gas and the carrier gas to the treatment container 11.

(2) Process (b2) of Supplying the First Catalyst Gas, then Performing Purging, and then Supplying the Source Gas

In the present process (b2), first, the first catalyst gas is supplied into the treatment container 11, then the inside of the treatment container 11 is purged with the purge gas, and then the source gas is supplied into the treatment container 11 (S2-2).

When the first catalyst gas is supplied to the treatment container 11, first, the carrier gas is supplied from the carrier gas supply path 17B to the first catalyst gas supply portion 13. The details of the carrier gas are as described above. In addition, the flow rate of the supply of the carrier gas is controlled by the MFC.

When the carrier gas is supplied to the first catalyst gas supply portion 13, the carrier gas is discharged from the first catalyst gas supply path 22 together with the first catalyst gas obtained by vaporizing the first catalyst stored in a liquid state in the first catalyst gas supply portion 13. In the first catalyst gas supply path 22, the opening/closing valve 22b is in an opened state by the opening/closing control, and the mixture gas including the carrier gas and the first catalyst gas is supplied into the treatment container 11 while the flow rate of the mixture gas is adjusted by the needle valve 22a.

When the mixture gas including the first catalyst gas and the carrier gas is supplied to the treatment container 11, the first catalyst gas is adsorbed on the surface of the substrate W,

The supply flow rate of the mixture gas including the first catalyst gas and the carrier gas (supply flow rate of first catalyst gas in the case of only first catalyst gas) is preferably in a range of 1 sccm or more and 10000 sccm or less, more preferably in a range of 100 sccm or more and 5000 sccm or less, and particularly preferably in a range of 200 sccm or more and 2000 sccm or less. By setting the supply flow rate of the mixture gas (or first catalyst gas) to 1 sccm or more, the reaction rate (film formation rate) of the source gas can be favorably maintained, and the adsorption of the source gas onto the substrate W can be prevented from becoming insufficient. On the other hand, by setting the supply flow rate of the mixture gas (or first catalyst gas) to 10000 sccm or less, the consumption amount can be reduced. The supply flow rate of the mixture gas (or first catalyst gas) can be appropriately controlled by adjusting the temperature of the first catalyst gas, the flow rate of the carrier gas, and the pressure in the first catalyst gas supply portion 13. Note that the supply flow rate of the carrier gas to be mixed with the first catalyst gas is not particularly limited, and can be appropriately set according to the supply flow rate of the mixture gas described above.

The supply time of the mixture gas including the first catalyst gas and the carrier gas to the treatment container 11 (pulse time. Supply time of first catalyst gas in the case of only first catalyst gas) is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the mixture gas (or first catalyst gas) to 0.1 seconds or more, the reaction rate (film formation rate) of the source gas can be favorably maintained, and the adsorption of the source gas onto the substrate W can be prevented from becoming insufficient. On the other hand, by setting the supply time of the mixture gas (or first catalyst gas) to 600 seconds or less, the consumption amount can be reduced, and the process time can be shortened. The supply time of the mixture gas (or first catalyst gas) can be appropriately controlled by adjusting the temperature of the first catalyst gas, the flow rate of the carrier gas, and the pressure in the first catalyst gas supply portion 13. Note that the supply time of the first catalyst gas means a time during which the opening/closing valve 22b is opened.

While the mixture gas including the first catalyst gas and the carrier gas is supplied into the treatment container 11, all of the opening/closing valve 21b of the source gas supply path 21, the opening/closing valve 23b of the second catalyst gas supply path 23, the opening/closing valve 24b of the reaction gas supply path 24, and the opening/closing valve 25a of the purge gas supply path 25 are in a closed state by the opening/closing control.

Subsequently, the inside of the treatment container 11 is purged in order to remove the first catalyst gas from the inside of the treatment container 11. Specifically, the opening/closing valve 25a of the purge gas supply path 25 is brought into an opened state by the opening/closing control, and the third purge gas is supplied from the purge gas supply path 25 to the treatment container IL In addition, the APC valve 27 is brought into an opened state, and the inside of the treatment container 11 is evacuated by the vacuum pump or the like (not shown). As a result, the atmosphere such as the first catalyst gas and the carrier gas is removed from the treatment container 11. The third purge gas is not particularly limited, and examples include inert gases such as nitrogen gas, helium gas, and argon gas. In addition, the third purge gas that does not contain moisture as much as possible is preferable.

The supply flow rate and the supply time of the third purge gas are not particularly limited as long as the first catalyst gas not adsorbed on the surface of the substrate W, impurities such as moisture contained in the first catalyst gas, and the like are sufficiently removed from the inside of the treatment container 11.

Note that while the third purge gas is supplied into the treatment container 11, all of the opening/closing valve 21b of the source gas supply path 21, the opening/closing valve 22b of the first catalyst gas supply path 22, the opening/closing valve 23b of the second catalyst gas supply path 23, and the opening/closing valve 24b of the reaction gas supply path 24 are in a closed state by the opening/closing control.

When the purge using the third purge gas is ended, the opening/closing valve 25a is brought into a closed state by the opening/closing control, and the supply of the third purge gas to the treatment container 11 is stopped.

Next, the source gas is supplied into the treatment container 11 from which the first catalyst gas has been removed. That is, the carrier gas whose flow rate is controlled by the MFC is supplied from the carrier gas supply path 17A to the source gas supply portion 12. When the carrier gas is supplied to the source gas supply portion 12, the carrier gas is discharged from the source gas supply path 21 together with the source gas obtained by vaporizing the source stored in a liquid state in the source gas supply portion 12. In the source gas supply path 21, the opening/closing valve 21b is in an opened state by the opening/closing control, and the mixture gas including the carrier gas and the source gas is supplied into the treatment container 11 while the flow rate of the mixture gas is adjusted by the needle valve 21a. Note that the details of the source gas and the carrier gas are as described above in the process (b1). Accordingly, details thereof will be omitted.

The supply flow rate of the mixture gas including the source gas and the carrier gas (supply flow rate of source gas in the case of only source gas) is preferably in a range of 1 sccm or more and 5000 sccm or less, more preferably in a range of 100 sccm or more and 3000 sccm or less, and particularly preferably in a range of 200 sccm or more and 2000 sccm or less. By setting the supply flow rate of the mixture gas (or source gas) to 1 sccm or more, the reaction rate (film formation rate) of the source gas can be favorably maintained, and the adsorption of the source gas onto the substrate W can be prevented from becoming insufficient. On the other hand, by setting the supply flow rate of the mixture gas (or source gas) to 5000 sccm or less, the gas consumption amount can be reduced. The supply flow rate of the mixture gas (or source gas) can be appropriately controlled by adjusting the temperature of the source gas, the flow rate of the carrier gas, and the pressure in the source gas supply portion 12. Note that the supply flow rate of the carrier gas to be mixed with the source gas is not particularly limited, and can be appropriately set according to the supply flow rate of the mixture gas described above.

The supply time of the mixture gas including the source gas and the carrier gas to the treatment container 11 (pulse time. Supply time of source gas in the case of only source gas) is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the mixture gas (or source gas) to 0.1 seconds or more, the reaction rate (film formation rate) of the source gas can be favorably maintained, and the adsorption of the source gas onto the substrate W can be prevented from becoming insufficient.

On the other hand, by setting the supply time of the mixture gas (or source gas) to 600 seconds or less, the consumption amount can be reduced, and the process time can be shortened. The supply time of the mixture gas (or source gas) can be appropriately controlled by adjusting the temperature of the source gas, the flow rate of the carrier gas, and the pressure in the source gas supply portion 12. Note that the supply time of the source gas means a time during which the opening/closing valve 21b is opened.

When the source gas is supplied into the treatment container 11, the source gas reacts with the OH group on the surface of the substrate W and is adsorbed. At this time, since the OH group has a charge distribution biased to negative charges due to the action of the first catalyst gas, the source gas can be easily adsorbed to the surface of the substrate W.

In the present process (b2), even when an inexpensive commercially available product is used as the first catalyst gas, a highly accurate film having high film uniformity can be formed. That is, a commercially available catalyst has a purity of about 98 mass % in a general product and a purity of about 99.5 mass % in a high purity product, and impurities such as moisture are contained in the catalyst even in the high purity product. Accordingly, for example, when the source gas and the first catalyst gas are simultaneously supplied to the treatment container 11 as in the process (b1) described above, moisture contained in the first catalyst gas reacts with the source gas, a thin film like those formed by a chemical vapor deposition (CVD) method is formed, and film uniformity may be deteriorated. However, as in the present process (b2), by supplying the first catalyst gas alone to the surface of the substrate W in advance to adsorb the first catalyst gas at an atomic layer level, and then purging the inside of the treatment container 11, it is possible to remove moisture contained in the first catalyst gas, then supply the source gas, and adsorb the source gas to the surface of the substrate W, As a result, a film having excellent film uniformity can be formed.

The temperature in the treatment container 11 at the time of supplying the first catalyst gas (or mixture gas with carrier gas) and the source gas (or mixture gas with carrier gas) (hereinafter, may be referred to as the “first catalyst gas and the like”) is in each case preferably in a range of 200° C. or lower, more preferably in a range of 50° C. or higher and 150° C. or lower, and particularly preferably in a range of 80° C. or higher and 125° C. or lower. By setting the temperature in the treatment container 11 to 200° C. or lower, for example, even when the substrate W is made of a material having a low heat-resistant temperature, it is possible to form a film while avoiding the thermal effect as much as possible and maintaining the material characteristics of the substrate W.

The pressure in the treatment container 11 when the first catalyst gas and the like is supplied is in each case preferably in a range of 1 Pa or more and 40000 Pa or less, more preferably in a range of 13 Pa or more and 13300 Pa or less, and particularly preferably in a range of 133 Pa or more and 6700 Pa or less. By setting the pressure in the treatment container 11 to 1 Pa or more, the reaction rate (film formation rate) of the source gas can be favorably maintained. On the other hand, by setting the pressure in the treatment container 11 to 40000 Pa or less, it is possible to shorten the treatment time and increase the purge efficiency. Note that the pressure in the treatment container 11 can be adjusted by controlling opening/closing of the APC valve 27 by PID control,

Note that while the source gas is supplied into the treatment container 11, all of the opening/closing valve 22b of the first catalyst gas supply path 22, the opening/closing valve 23b of the second catalyst gas supply path 23, the opening/closing valve 24b of the reaction gas supply path 24, and the opening/closing valve 25a of the purge gas supply path 25 are in a closed state by the opening/closing control.

When the supply of the source gas is ended, the opening/closing valve 21b is brought into a closed state by the opening/closing control, and the supply of the mixture gas of the source gas and the carrier gas is stopped.

### (3) Process (b3) of Supplying Only the Source Gas

In the present process (b3), only the source gas is supplied to the treatment container 11 (S2-3).

It has been found that when a source gas having an amino group is used as the source gas, the source can be (chemically) adsorbed to the surface of the substrate W without interposing a catalyst. As a result, the supply of the first catalyst gas to the treatment container 11 can be omitted, and productivity (throughput) can be significantly improved.

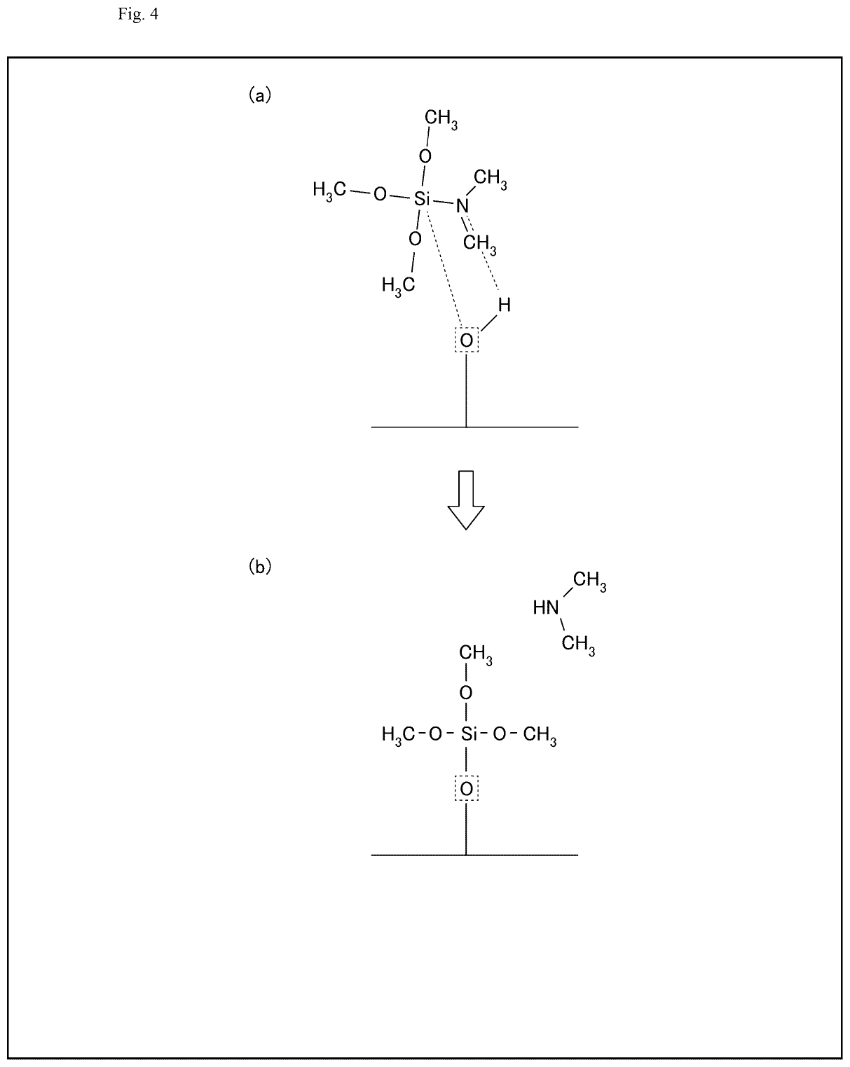

For example, in a case where the source gas is Si(NMe₂)(OMe)₃ gas (see FIG. 4), when Si(NMe₂)(OMe)₃ comes into contact with the surface of the substrate W, N atoms in Si(NMe₂)(OMe)₃ react with H atoms in the OH group present on the surface of SiO₂ constituting the substrate W, and at the same time, Si(NMe₂)(OMe)₃ of the source gas has a positive charge bias on Si atoms, so that the reaction occurs and produces (CH₃)₂NH as a by-product. Note that FIG. 4 is a schematic diagram illustrating a state in which the source gas is adsorbed on the substrate when only the source gas is supplied into the treatment container 11 in the present embodiment,

When the source gas is supplied to the treatment container 11, the carrier gas whose flow rate is controlled by the MFC is supplied from the carrier gas supply path 17A to the source gas supply portion 12. When the carrier gas is supplied to the source gas supply portion 12, the carrier gas is discharged from the source gas supply path 21 together with the source gas obtained by vaporizing the source stored in a liquid state in the source gas supply portion 12. In the source gas supply path 21, the opening/closing valve 21b is in an opened state by the opening/closing control, and the mixture gas including the carrier gas and the source gas is supplied into the treatment container 11 while the flow rate of the mixture gas is adjusted by the needle valve 21a. Note that the details of the source gas and the carrier gas are as described above in the process (b1). Accordingly, details thereof will be omitted.

The supply flow rate of the mixture gas including the source gas and the carrier gas (supply flow rate of source gas in the case of only source gas) is preferably in a range of 1 sccm or more and 5000 sccm or less, more preferably in a range of 100 sccm or more and 3000 sccm or less, and particularly preferably in a range of 200 sccm or more and 2000 sccm or less. By setting the supply flow rate of the mixture gas (or source gas) to 1 sccm or more, the reaction rate (film formation rate) of the source gas can be favorably maintained, and the adsorption of the source gas onto the substrate W can be prevented from becoming insufficient. On the other hand, by setting the supply flow rate of the mixture gas (or source gas) to 5000 sccm or less, the gas consumption amount can be reduced. The supply flow rate of the mixture gas (or source gas) can be appropriately controlled by adjusting the temperature of the source gas, the flow rate of the carrier gas, and the pressure in the source gas supply portion 12. Note that the supply flow rate of the carrier gas to be mixed with the source gas is not particularly limited, and can be appropriately set according to the supply flow rate of the mixture gas described above.

The supply time of the mixture gas including the source gas and the carrier gas to the treatment container 11 (pulse time. Supply time of source gas in the case of only source gas) is preferably in a range of 0.1 seconds or more and 300 seconds or less, more preferably in a range of 1 second or more and 120 seconds or less, and particularly preferably in a range of 10 seconds or more and 60 seconds or less. By setting the supply time of the mixture gas (or source gas) to 0.1 seconds or more, the reaction rate (film formation rate) of the source gas can be favorably maintained, and the adsorption of the source gas onto the substrate W can be prevented from becoming insufficient. On the other hand, by setting the supply time of the mixture gas (or source gas) to 300 seconds or less, the consumption amount can be reduced, and the process time can be shortened. The supply time of the mixture gas (or source gas) can be appropriately controlled by adjusting the temperature of the source gas, the flow rate of the carrier gas, and the pressure in the source gas supply portion 12.

Further, the temperature in the treatment container 11 at the time of supplying the source gas (or mixture gas with carrier gas) is preferably in a range of 200° C. or lower, more preferably in a range of 50° C. or higher and 150° C. or lower, and particularly preferably in a range of 80° C. or higher and 125° C. or lower. By setting the temperature in the treatment container 11 to 200° C. or lower, for example, even when the substrate W is made of a material having a low heat-resistant temperature, it is possible to form a film while avoiding the thermal effect as much as possible and maintaining the material characteristics of the substrate W,

In addition, the pressure in the treatment container 11 when the source gas (or mixture gas with carrier gas) is supplied is preferably in a range of 1 Pa or more and 13300 Pa or less, more preferably in a range of 7 Pa or more and 2660 Pa or less, and particularly preferably in a range of 67 Pa or more and 1330 Pa or less. By setting the pressure in the treatment container 11 to 1 Pa or more, the reaction rate (film formation rate) of the source gas can be favorably maintained. On the other hand, by setting the pressure in the treatment container 11 to 13000 Pa or less, it is possible to shorten the treatment time and increase the purge efficiency. Note that the pressure in the treatment container 11 can be adjusted by controlling opening/closing of the APC valve 27 by PID control.

Note that while the source gas is supplied into the treatment container 11, all of the opening/closing valve 22b of the first catalyst gas supply path 22, the opening/closing valve 23b of the second catalyst gas supply path 23, the opening/closing valve 24b of the reaction gas supply path 24, and the opening/closing valve 25a of the purge gas supply path 25 are in a closed state by the opening/closing control.

When the supply of the source gas is ended, the opening/closing valve 21b is brought into a closed state by the opening/closing control, and the supply of the mixture gas of the source gas and the carrier gas is stopped.

### (4) Purge Process

An object of the purge process (S2-4) is to remove the atmosphere in the treatment container 11 in the source gas supply process (B). Specifically, when the source gas supply process (B) is the process (b1) of supplying the first catalyst gas together with the source gas, the object is to remove an unreacted source gas, a by-product gas, the first catalyst gas, and the like from the inside of the treatment container 11. In addition, when the source gas supply process (B) is the process (b2) of supplying the first catalyst gas, then performing purging, and further supplying the source gas and the process (b3) of supplying only the source gas, the object is to remove un unreacted source gas, a by-product gas, and the like.

Specifically, the purge process brings the opening/closing valve 25a into an opened state by the opening/closing control, and supplies the first purge gas from the purge gas supply path 25 to the treatment container 11. In addition, the APC valve 27 is brought into an opened state, and the inside of the treatment container 11 is evacuated by the vacuum pump or the like (not shown). As a result, the unreacted source gas and the like are removed from the treatment container 11. The first purge gas is not particularly limited, and examples include inert gases such as nitrogen gas, helium gas, and argon gas. In addition, the first purge gas that does not contain moisture as much as possible is preferable.

The supply flow rate and the supply time of the first purge gas are not particularly limited as long as unreacted source gas, the by-product gas, the first catalyst gas, and the like can be sufficiently removed from the inside of the treatment container 11. Note that while the first purge gas is supplied into the treatment container 11, each of the opening/closing valve 21b of the source gas supply path 21, the opening/closing valve 22b of the first catalyst gas supply path 22, the opening/closing valve 23b of the second catalyst gas supply path 23, and the opening/closing valve 24b of the reaction gas supply path 24 is in a closed state by the opening/closing control.

When the purge using the first purge gas is ended, the opening/closing valve 25a is brought into a closed state by the opening/closing control, and the supply of the first purge gas to the treatment container 11 is stopped.

### [Reaction Gas Supply Process (C)J

The reaction gas supply process (C) of the present embodiment is a process of supplying the reaction gas into the treatment container 11 after the source gas supply process (B) to oxidize the source gas adsorbed onto the substrate W, and then purging the inside of the treatment container 11 with the second purge gas (S3).

In the reaction gas supply process (C), as shown in FIG. 2, the (chemical) adsorption of the source gas to the substrate W is any of a case of a process (c1) of supplying the second catalyst gas into the treatment container 11 together with the reaction gas (S3-1), a case of a process (c2) of supplying the second catalyst gas into the treatment container 11 before supplying the reaction gas, and then performing purging with the second purge gas (S3-2), and a case of a process (c3) of supplying only the reaction gas into the treatment container 11 (S3-3). Hereinafter, the process (c1) the process (c2), and the process (c3), and the purge process with the second purge gas will be sequentially described,

(1) Process (c1) of Supplying the Second Catalyst Gas Together with the Reaction Gas

In the present process (ci), the reaction gas and the second catalyst gas are simultaneously supplied to the treatment container 11 (S3-1).

When the reaction gas is supplied to the treatment container 11, the carrier gas is supplied from the carrier gas supply path 17D to the reaction gas supply portion 15, The carrier gas is not particularly limited, and examples thereof include inert gases such as nitrogen gas, argon gas, and helium gas. These inert gases can be used alone or in combination. In addition, the flow rate of the supply of the carrier gas is controlled by the MFC.

When the carrier gas is supplied to the reaction gas supply portion 15, the carrier gas is discharged from the reaction gas supply path 24 together with the reaction gas obtained by vaporizing the oxidant stored in a liquid state in the reaction gas supply portion 15. In the reaction gas supply path 24, the opening/closing valve 24b is in an opened state by the opening/closing control, and the mixture gas including the carrier gas and the reaction gas is supplied into the treatment container 11 while the flow rate of the mixture gas is adjusted by the needle valve 24a.

The reaction gas is preferably an oxidant gas having an oxygen atom. The oxidant gas is preferably, for example, at least one type of gas selected from a group consisting of water, hydrogen peroxide water, formic acid, and aldehyde.

The supply flow rate of the mixture gas including the reaction gas and the carrier gas (supply flow rate of reaction gas in the case of only reaction gas) is preferably in a range of 1 sccm or more and 20000 sccm or less, more preferably in a range of 100 sccm or more and 10000 sccm or less, and particularly preferably in a range of 200 sccm or more and 5000 sccm or less. By setting the supply flow rate of the mixture gas (or reaction gas) to 1 sccm or more, it is possible to prevent the OH group from being insufficiently introduced into the adsorbed molecule of the source gas adsorbed on the surface of the substrate W. On the other hand, by setting the supply flow rate of the mixture gas (or reaction gas) to 20000 sccm or less, the consumption of the source can be reduced and the purge efficiency can be improved. The supply flow rate of the mixture gas (or reaction gas) can be appropriately controlled by adjusting the temperature of the reaction gas, the flow rate of the carrier gas, and the pressure in the reaction gas supply portion 15. Note that the supply flow rate of the carrier gas to be mixed with the reaction gas is not particularly limited, and can be appropriately set according to the supply flow rate of the mixture gas described above.

In addition, when the second catalyst gas is supplied to the treatment container 11, the carrier gas is supplied from the carrier gas supply path 17C to the second catalyst gas supply portion 14. The details of the carrier gas are as described above. In addition, the flow rate of the supply of the carrier gas is controlled by the MFC. Further, the carrier gas that does not contain moisture as much as possible is preferable.

When the carrier gas is supplied to the second catalyst gas supply portion 14, the carrier gas is discharged from the second catalyst gas supply path 23 together with the second catalyst gas obtained by vaporizing the second catalyst stored in the second catalyst gas supply portion 14. In the second catalyst gas supply path 23, the opening/closing valve 23b is in an opened state by the opening/closing control, and the mixture gas including the carrier gas and the second catalyst gas is supplied into the treatment container 11 while the flow rate of the mixture gas is adjusted by the needle valve 23a.

Examples of the second catalyst gas include those exemplified regarding the first catalyst gas described above. As the second catalyst gas, the same type or different types of the first catalyst gas can be used from those exemplified regarding the first catalyst gas. The second catalyst gas can be used in any combination with any of the above described exemplified source gas and first catalyst gas. In addition, the second catalyst gas that does not contain moisture as much as possible is preferable.

The supply flow rate of the mixture gas including the second catalyst gas and the carrier gas (supply flow rate of second catalyst gas in the case of only second catalyst gas) is preferably in a range of 1 sccm or more and 10000 sccm or less, more preferably in a range of 100 sccm or more and 000 sccm or less, and particularly preferably in a range of 200 sccm or more and 2000 sccm or less. By setting the supply flow rate of the mixture gas (or second catalyst gas) to 1 sccm or more, it is possible to prevent the OH group from being insufficiently introduced into the adsorbed molecule of the source gas adsorbed on the surface of the substrate W. On the other hand, by setting the supply flow rate of the mixture gas (or second catalyst gas) to 10000 sccm or less, the consumption amount can be reduced. The supply flow rate of the mixture gas (or second catalyst gas) can be appropriately controlled by adjusting the temperature of the second catalyst gas, the flow rate of the carrier gas, and the pressure in the second catalyst gas supply portion 14. Note that the supply flow rate of the carrier gas to be mixed with the second catalyst gas is not particularly limited, and can be appropriately set according to the supply flow rate of the mixture gas described above.

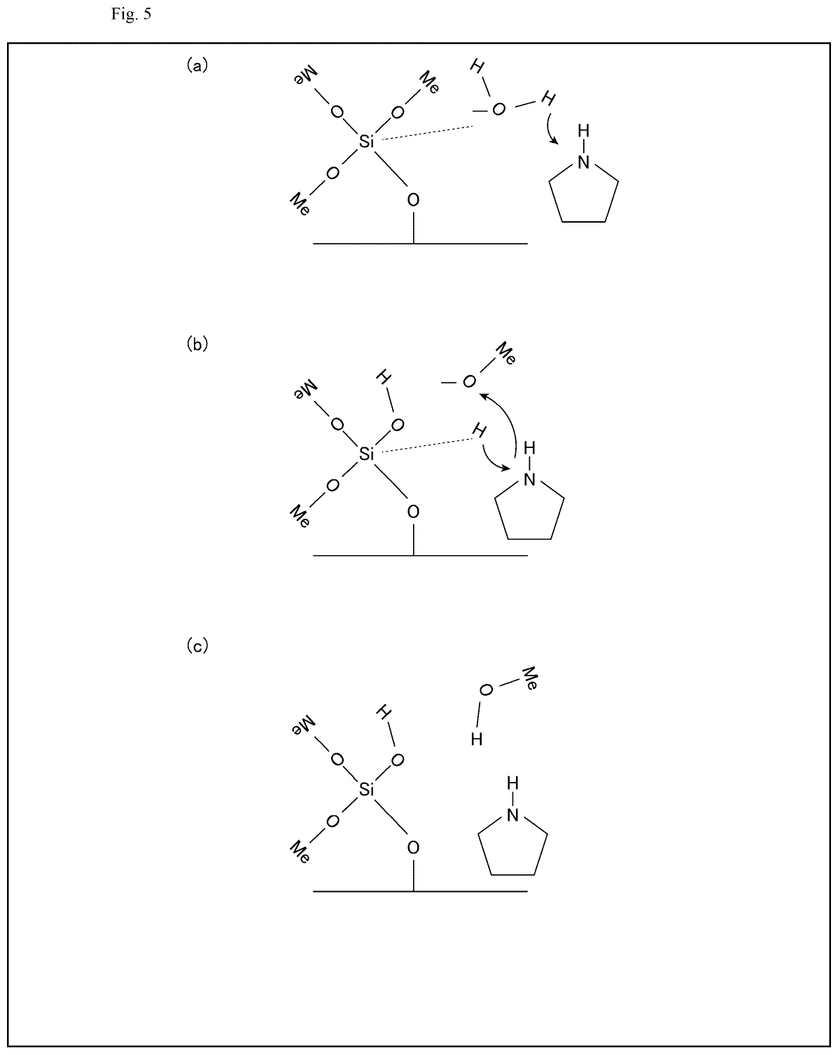

When the mixture gas including the reaction gas and the carrier gas and the mixture gas including the second catalyst gas and the carrier gas are supplied to the treatment container 11, the reaction gas introduces OH groups into the adsorbed molecule of the source gas adsorbed on the surface of the substrate W. In the present embodiment, the second catalyst gas is supplied into the treatment container 11 simultaneously with the reaction gas, thereby improving the introduction of the OH group into the adsorbed molecule. For example, when a —Si(OMe)₃ group is bonded to the surface of the substrate W by siloxane bonding, the reaction gas is H₂O, and the second catalyst gas is a pyrrolidine gas (see FIG. 5), when the pyrrolidine gas comes into contact with H₂O, the lone electron pair of the N atom in the pyrrolidine abstracts the H atom from H₂O. As a result, the charge distribution is biased to negative charges for the O atom of the OH group, and the OH group is bonded to a Si atom whose charge distribution is biased to positive charges by an oxidation reaction so as to replace a ligand (—OMe group) in the —Si(OMe)₃ group bonded to the surface of the substrate W. In addition, the ligand MeO⁻ desorbed from the —Si(OMe)₃ group at this time is bonded to the H atom extracted by pyrrolidine, thereby producing MeOH as a by-product. Note that FIG. 5 is a schematic diagram illustrating a state in which an OH group is introduced into the adsorbed molecule adsorbed on the surface of the substrate W when the reaction gas and the second catalyst gas are simultaneously supplied in the present embodiment.

The temperature in the treatment container 11 at the time of supplying the reaction gas (or mixture gas with carrier gas) and the second catalyst gas (or mixture gas with carrier gas) is preferably in a range of 200° C. or lower, more preferably in a range of 50° C. or higher and 150° C. or lower, and particularly preferably in a range of 80° C. or higher and 125° C. or lower. By setting the temperature in the treatment container 1 Ito 200° C. or lower, for example, even when the substrate W is made of a material having a low heat-resistant temperature, it is possible to form a film while avoiding the thermal effect as much as possible and maintaining the material characteristics of the substrate W.

The pressure in the treatment container 11 at the time of supplying the reaction gas (or mixture gas with carrier gas) and the second catalyst gas (or mixture gas with carrier gas) is preferably in a range of 1 Pa or more and 40000 Pa or less, more preferably in a range of 13 Pa or more and 13300 Pa or less, and particularly preferably in a range of 133 Pa or more and 6700 Pa or less. By setting the pressure in the treatment container 11 to 1 Pa or more, the reaction rate (film formation rate) of the reaction gas can be favorably maintained. On the other hand, by setting the pressure in the treatment container It to 40000 Pa or less, it is possible to shorten the treatment time and increase the purge efficiency, Note that the pressure in the treatment container 11 can be adjusted by controlling opening/closing of the APC valve 27 by PID control,

The supply time (pulse time) of the reaction gas (or mixture gas with carrier gas) and the second catalyst gas (or mixture gas with carrier gas) to the treatment container 11 is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the reaction gas and the like to 0.1 seconds or more, it is possible to prevent the OH group from being insufficiently introduced into the adsorbed molecule of the source gas adsorbed on the surface of the substrate W. On the other hand, by setting the supply time of the reaction gas and the like to 600 seconds or less, the consumption amount can be reduced, and the process time can be shortened. The supply time of the reaction gas and the like can be appropriately controlled by adjusting the temperature of the reaction gas and the second catalyst gas, the flow rate of the carrier gas, the pressure in the reaction gas supply portion 15, and the pressure of the second catalyst gas supply portion 14. In addition, the supply time of the reaction gas and the second catalyst gas means a time during which the opening/closing valve 24b and the opening/closing valve 23b are simultaneously opened.

In the present process (c1), during the supply of the reaction gas (or mixture gas with carrier gas) and the second catalyst gas (or mixture gas with carrier gas), all of the opening/closing valve 21b of the source gas supply path 21, the opening/closing valve 22b of the first catalyst gas supply path 22, and the opening/closing valve 25a of the purge gas supply path 25 are in a closed state. In addition, the end of the present process (c1) is performed by bringing the opening/closing valve 23b and the opening/closing valve 24b into a closed state by the opening/closing control and stopping the supply of the mixture gas of the reaction gas and the carrier gas and the mixture gas of the second catalyst gas and the carrier gas to the treatment container 11.

(2) Process (c2) of Supplying the Second Catalyst Gas, then Performing Purging, and then Supplying the Reaction Gas

In the process (c2), first, the second catalyst gas is supplied into the treatment container 11, then the inside of the treatment container 11 is purged with the purge gas, and then the source gas is supplied into the treatment container 11 (53-2). Here, when the second catalyst gas is supplied to the treatment container 11, first, the carrier gas is supplied from the carrier gas supply path 17C to the second catalyst gas supply portion 14. The details of the carrier gas are as described above. In addition, the flow rate of the supply of the carrier gas is controlled by the MFC.

When the carrier gas is supplied to the second catalyst gas supply portion 14, the carrier gas is discharged from the second catalyst gas supply path 23 together with the second catalyst gas obtained by vaporizing the second catalyst stored in a liquid state in the second catalyst gas supply portion 14. In the second catalyst gas supply path 23, the opening/closing valve 23b is in an opened state by the opening/closing control, and the mixture gas including the carrier gas and the second catalyst gas is supplied into the treatment container 11 while the flow rate of the mixture gas is adjusted by the needle valve 23a.

The supply flow rate of the mixture gas including the second catalyst gas and the carrier gas (supply flow rate of second catalyst gas in the case of only second catalyst gas) is preferably in a range of 1 sccm or more and 10000 sccm or less, more preferably in a range of 100 sccm or more and 5000 sccm or less, and particularly preferably in a range of 200 sccm or more and 2000 sccm or less. By setting the supply flow rate of the mixture gas (or second catalyst gas) to 1 sccm or more, it is possible to prevent the OH group from being insufficiently introduced into the adsorbed molecule of the source gas adsorbed on the surface of the substrate W. On the other hand, by setting the supply flow rate of the mixture gas (or second catalyst gas) to 10000 sccm or less, the consumption amount can be reduced. The supply flow rate of the mixture gas (or second catalyst gas) can be appropriately controlled by adjusting the temperature of the second catalyst gas, the flow rate of the carrier gas, and the pressure in the second catalyst gas supply portion 14. Note that the supply flow rate of the carrier gas to be mixed with the second catalyst gas is not particularly limited, and can be appropriately set according to the supply flow rate of the mixture gas described above.

The supply time of the mixture gas including the second catalyst gas and the carrier gas to the treatment container 11 (pulse time. Supply time of second catalyst gas in the case of only second catalyst gas) is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the mixture gas (or second catalyst gas) to 0.1 seconds or more, the reaction between the second catalyst gas and the adsorbed molecule of the source gas adsorbed on the surface of the substrate W can be favorably maintained. On the other hand, by setting the supply time of the mixture gas (or second catalyst gas) to 600 seconds or less, the consumption amount can be reduced, and the process time can be shortened. The supply time of the mixture gas (or second catalyst gas) can be appropriately controlled by adjusting the temperature of the second catalyst gas, the flow rate of the carrier gas, and the pressure in the second catalyst gas supply portion 14. Note that the supply time of the second catalyst gas means a time during which the opening/closing valve 23b is opened.

While the mixture gas including the second catalyst gas and the carrier gas is supplied into the treatment container 11, all of the opening/closing valve 21b of the source gas supply path 21, the opening/closing valve 22b of the first catalyst gas supply path 22, the opening/closing valve 24b of the reaction gas supply path 24, and the opening/closing valve 25a of the purge gas supply path 25 are in a closed state by the opening/closing control.

Subsequently, the inside of the treatment container 11 is purged in order to remove the second catalyst gas from the inside of the treatment container 11. Specifically, the opening/closing valve 25a of the purge gas supply path 25 is brought into an opened state by the opening/closing control, and a fourth purge gas is supplied from the purge gas supply path 25 to the treatment container 11. In addition, the APC valve 27 is brought into an opened state, and the inside of the treatment container 11 is evacuated by the vacuum pump or the like (not shown). As a result, the second catalyst gas is removed from the treatment container 11. The fourth purge gas is not particularly limited, and examples include inert gases such as nitrogen gas, helium gas, and argon gas. In addition, the fourth purge gas that does not contain moisture as much as possible is preferable.

The supply flow rate and the supply time of the fourth purge gas are not particularly limited as long as the second catalyst gas can be sufficiently removed from the inside of the treatment container 11.

Note that while the third purge gas is supplied into the treatment container 11, all of the opening/closing valve 21b of the source gas supply path 21, the opening/closing valve 22b of the first catalyst gas supply path 22, the opening/closing valve 23b of the second catalyst gas supply path 23, and the opening/closing valve 24b of the reaction gas supply path 24 are in a closed state by the opening/closing control.

When the purge using the fourth purge gas is ended, the opening/closing valve 25a is brought into a closed state by the opening/closing control, and the supply of the fourth purge gas to the treatment container 11 is stopped.

Next, the reaction gas is supplied into the treatment container 11 from which the second catalyst gas has been removed. That is, the carrier gas whose flow rate is controlled by the MFC is supplied from the carrier gas supply path 17D to the reaction gas supply portion 15. When the carrier gas is supplied to the reaction gas supply portion 15, the carrier gas is discharged from the reaction gas supply path 24 together with the reaction gas obtained by vaporizing the oxidant stored in a liquid state in the reaction gas supply portion 15. In the reaction gas supply path 24, the opening/closing valve 24b is in an opened state by the opening/closing control, and the mixture gas including the carrier gas and the reaction gas is supplied into the treatment container 11 while the flow rate of the mixture gas is adjusted by the needle valve 24a. Note that the details of the reaction gas and the carrier gas are as described above in the process (c1). Accordingly, details thereof will be omitted.

The supply flow rate of the mixture gas including the reaction gas and the carrier gas (supply flow rate of reaction gas in the case of only reaction gas) is preferably in a range of 1 sccm or more and 20000 sccm or less, more preferably in a range of 100 sccm or more and 10000 sccm or less, and particularly preferably in a range of 200 sccm or more and 5000 sccm or less. By setting the supply flow rate of the mixture gas (or reaction gas) to 1 sccm or more, it is possible to prevent the OH group from being insufficiently introduced into the adsorbed molecule of the source gas adsorbed on the surface of the substrate W. On the other hand, by setting the supply flow rate of the mixture gas (or reaction gas) to 20000 sccm or less, the consumption of the source can be reduced and the purge efficiency can be improved. The supply flow rate of the mixture gas (or reaction gas) can be appropriately controlled by adjusting the temperature of the reaction gas, the flow rate of the carrier gas, and the pressure in the reaction gas supply portion 15. Note that the supply flow rate of the carrier gas to be mixed with the reaction gas is not particularly limited, and can be appropriately set according to the supply flow rate of the mixture gas described above.

The supply time of the mixture gas including the reaction gas and the carrier gas to the treatment container 11 (pulse time. Supply time of reaction gas in the case of only reaction gas) is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the mixture gas (or reaction gas) to 0.1 seconds or more, the introduction of the OH group into the adsorbed molecule of the source gas adsorbed on the surface of the substrate W by the reaction gas can be favorably maintained. On the other hand, by setting the supply time of the mixture gas (or reaction gas) to 600 seconds or less, the consumption amount can be reduced, and the process time can be shortened. The supply time of the mixture gas (or reaction gas) can be appropriately controlled by adjusting the temperature of the reaction gas, the flow rate of the carrier gas, and the pressure in the reaction gas supply portion 15. Note that the supply time of the reaction gas means a time during which the opening/closing valve 24b is opened.

When the reaction gas is supplied into the treatment container 11, the reaction gas introduces the OH group into the adsorbed molecule of the source gas adsorbed on the surface of the substrate W, Then, the second catalyst gas supplied in advance acts on the adsorbed molecule of the source gas adsorbed on the surface of the substrate W so that the oxidation reaction with the reaction gas is promoted (see FIG. 3).

The temperature in the treatment container 11 at the time of supplying the second catalyst gas (or mixture gas with carrier gas) and the reaction gas (or mixture gas with carrier gas) is preferably in a range of 200° C. or lower, more preferably in a range of SOC or higher and 150° C. or lower, and particularly preferably in a range of 80° C. or higher and 125° C. or lower. By setting the temperature in the treatment container 11 to 200° C. or lower, for example, even when the substrate W is made of a material having a low heat-resistant temperature, it is possible to form a film while avoiding the thermal effect as much as possible and maintaining the material characteristics of the substrate W.

The pressure in the treatment container 11 at the time of supplying the second catalyst gas (or mixture gas with carrier gas) and the reaction gas (or mixture gas with carrier gas) is preferably in a range of 1 Pa or more and 40000 Pa or less, more preferably in a range of 13 Pa or more and 13300 Pa or less, and particularly preferably in a range of 133 Pa or more and 6700 Pa or less. By setting the pressure in the treatment container 11 to 1 Pa or more, the reaction rate (film formation rate) of the reaction gas can be favorably maintained. On the other hand, by setting the pressure in the treatment container 11 to 40000 Pa or less, it is possible to shorten the treatment time and increase the purge efficiency. Note that the pressure in the treatment container 11 can be adjusted by controlling opening/closing of the APC valve 27 by PID control.

Note that while the reaction gas is supplied into the treatment container 11, all of the opening/closing valve 21b of the source gas supply path 21, the opening/closing valve 22b of the first catalyst gas supply path 22, the opening/closing valve 23b of the second catalyst gas supply path 23, and the opening/closing valve 25a of the purge gas supply path 25 are in a closed state by the opening/closing control.

When the supply of the reaction gas is ended, the opening/closing valve 24b is brought into a closed state by the opening/closing control, and the supply of the mixture gas of the reaction gas and the carrier gas is stopped.

### (3) Process (c3) of Supplying Only the Reaction Gas

In the present process (c3), only the reaction gas is supplied to the treatment container 11 (S3-3).

In the present process (c3), the OH group is introduced into the adsorbed molecule of the source gas adsorbed on the surface of the substrate W without supplying the second catalyst gas to the treatment container 11. Therefore, productivity (throughput) can be significantly improved. Note that the present process (c3) is not performed when the source gas supply process (B) is the process (b3) of supplying only the source gas to the treatment container 11.

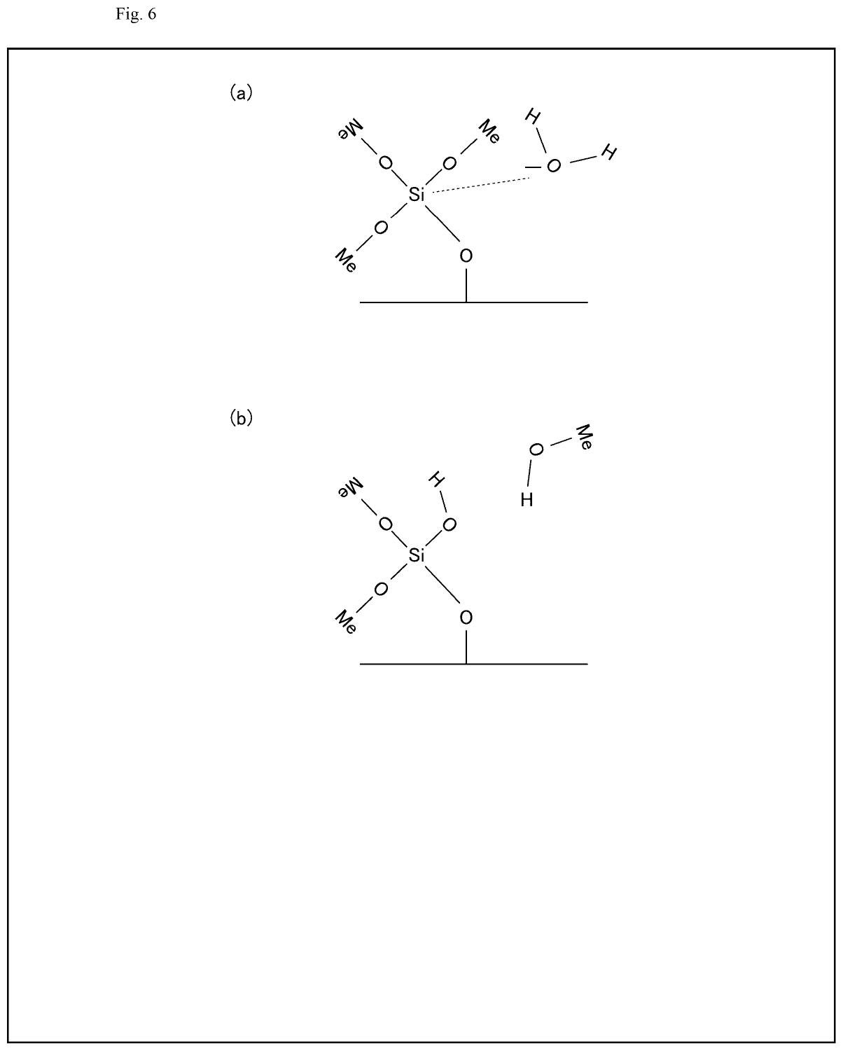

For example, in a case where a —Si(OMe)₃ group is bonded to the surface of the substrate W by siloxane bonding and the reaction gas is H₂O, when H₂O comes into contact with the —Si(OMe)₃ group, the OH group is bonded to a Si atom whose charge distribution is biased to positive charges by an oxidation reaction so as to replace a ligand (—OMe group) in the —Si(OMe)₃ group bonded to the surface of the substrate W (FIG. 6(a)). In addition, at this time, the ligand MeO⁻ desorbed from the —Si(OMe)₃ group is bonded to H⁺ of H₂O, whereby MeOH is produced as a by-product (FIG. 6(b)). Note that FIG. 6 is a schematic diagram illustrating a state in which an OH group is introduced into the adsorbed molecule adsorbed on the surface of the substrate W when only the reaction gas is supplied in the present embodiment.

When the reaction gas is supplied to the treatment container 11, the carrier gas whose flow rate is controlled by the MFC is supplied from the carrier gas supply path 17D to the reaction gas supply portion 15. When the carrier gas is supplied to the reaction gas supply portion 15, the carrier gas is discharged from the reaction gas supply path 24 together with the reaction gas obtained by vaporizing the oxidant stored in a liquid state in the reaction gas supply portion 15. In the reaction gas supply path 24, the opening/closing valve 24b is in an opened state by the opening/closing control, and the mixture gas including the carrier gas and the reaction gas is supplied into the treatment container 11 while the flow rate of the mixture gas is adjusted by the needle valve 24a. Note that the details of the reaction gas and the carrier gas are as described above in the process (c1). Accordingly, details thereof will be omitted.

The supply flow rate of the mixture gas including the reaction gas and the carrier gas (supply flow rate of reaction gas in the case of only reaction gas) is preferably in a range of 1 sccm or more and 20000 sccm or less, more preferably in a range of 100 sccm or more and 10000 sccm or less, and particularly preferably in a range of 200 sccm or more and 5000 sccm or less. By setting the supply flow rate of the mixture gas (or reaction gas) to 1 sccm or more, it is possible to prevent the OH group from being insufficiently introduced into the adsorbed molecule of the source gas adsorbed on the surface of the substrate W. On the other hand, by setting the supply flow rate of the mixture gas (or reaction gas) to 20000 sccm or less, the consumption of the source can be reduced and the purge efficiency can be improved. The supply flow rate of the mixture gas (or reaction gas) can be appropriately controlled by adjusting the temperature of the reaction gas, the flow rate of the carrier gas, and the pressure in the reaction gas supply portion 15. Note that the supply flow rate of the carrier gas to be mixed with the reaction gas is not particularly limited, and can be appropriately set according to the supply flow rate of the mixture gas described above.

The supply time of the mixture gas including the reaction gas and the carrier gas to the treatment container 11 (pulse time. Supply time of reaction gas in the case of only reaction gas) is preferably in a range of 0.1 seconds or more and 600 seconds or less, more preferably in a range of 1 second or more and 300 seconds or less, and particularly preferably in a range of 10 seconds or more and 180 seconds or less. By setting the supply time of the mixture gas (or reaction gas) to 0.1 seconds or more, the introduction of the OH group into the adsorbed molecule of the source gas adsorbed on the surface of the substrate W by the reaction gas can be favorably maintained On the other hand, by setting the supply time of the mixture gas (or reaction gas) to 600 seconds or less, the consumption amount can be reduced, and the process time can be shortened. The supply time of the mixture gas (or reaction gas) can be appropriately controlled by adjusting the temperature of the reaction gas, the flow rate of the carrier gas, and the pressure in the reaction gas supply portion IS. In addition, the supply time of the mixture gas (or reaction gas) means a time during which the opening/closing valve 24b is opened.

Further, the temperature in the treatment container 11 at the time of supplying the reaction gas (or mixture gas with carrier gas) is preferably 200° C. or lower, mom preferably in a range of 50° C. or higher and 150° C. or lower, and particularly preferably in a range of 80° C. or higher and 125° C. or lower. By setting the temperature in the treatment container 11 to 200° C. or lower, for example, even when the substrate W is made of a material having a low heat-resistant temperature, it is possible to form a film while avoiding the thermal effect as much as possible and maintaining the material characteristics of the substrate W.

In addition, the pressure in the treatment container 11 at the time of supplying the reaction gas (or mixture gas with carrier gas) is preferably in a range of 13 Pa or more and 40000 Pa or less, more preferably in a range of 133 Pa or more and 13300 Pa or less, and particularly preferably in a range of 1330 Pa or more and 6700 Pa or less. By setting the pressure in the treatment container 11 to 13 Pa or more, the reaction rate (film formation rate) of the reaction gas can be favorably maintained. On the other hand, by setting the pressure in the treatment container 11 to 40000 Pa or less, it is possible to shorten the treatment time and increase the purge efficiency. Note that the pressure in the treatment container 11 can be adjusted by controlling opening/closing of the APC valve 27 by PID control.

Note that while the reaction gas is supplied into the treatment container 11, all of the opening/closing valve 21b of the source gas supply 21, the opening/closing valve 22b of the first catalyst gas supply path 22, the opening/closing valve 23b of the second catalyst gas supply path 23, and the opening/closing valve 25a of the purge gas supply path 25 are in a closed state by the opening/closing control.

When the supply of the reaction gas is ended, the opening/closing valve 24b is brought into a closed state by the opening/closing control, and the supply of the mixture gas of the reaction gas and the carrier gas is stopped.

### (4) Purge Process

An object of the purge process (S3-4) is to remove the atmosphere in the treatment container 11 in the reaction gas supply process (C), Specifically, when the reaction gas supply process (C) is the process (c1) of supplying the second catalyst gas together with the reaction gas, the object is to remove an unreacted reaction gas, a by-product gas, the second catalyst gas, and the like from the inside of the treatment container 11, In addition, when the reaction gas supply process (C) is the process (c2) of supplying the second catalyst gas, then performing purging, and further supplying the reaction gas and the process (c3) of supplying only the reaction gas, the object is to remove un unreacted reaction gas, a by-product gas, and the like.

Specifically, the purge process brings the opening/closing valve 25a into an opened state by the opening/closing control, and supplies the second purge gas from the purge gas supply path 25 to the treatment container 11. In addition, the APC valve 27 is brought into an opened state, and the inside of the treatment container 11 is evacuated by the vacuum pump or the like (not shown). As a result, the unreacted reaction gas and the like are removed from the treatment container 11, The second purge gas is not particularly limited, and examples include inert gases such as nitrogen gas, helium gas, and argon gas. In addition, the second purge gas that does not contain moisture as much as possible is preferable.

The supply flow rate and the supply time of the second purge gas are not particularly limited as long as unreacted reaction gas, the by-product gas, the second catalyst gas, and the like can be sufficiently removed from the inside of the treatment container 11. Note that while the second purge gas is supplied into the treatment container 11, each of the opening/closing valve 21b of the source gas supply path 21, the opening/closing valve 22b of the first catalyst gas supply path 22, the opening/closing valve 23b of the second catalyst gas supply path 23, and the opening/closing valve 24b of the reaction gas supply path 24 is in a closed state by the opening/closing control.

When the purge using the second purge gas is ended, the opening/closing valve 25a is brought into a closed state by the opening/closing control, and the supply of the second purge gas to the treatment container 11 is stopped.

### [Other Matters]

In the film forming method of the present embodiment, for example, the two processes of the source gas supply process (B) and the reaction gas supply process (C) can be set as one cycle. By repeating the cycle of the source gas supply process (B) and the reaction gas supply process (C) a plurality of times, a film having a desired film thickness can be formed on the surface of the substrate W (S4). In addition, the film thickness of the film to be formed can be controlled at an atomic layer level. When the cycle of the source gas supply process (B) and the reaction gas supply process (C) is repeated a plurality of times, the process (b1), the process (b2), and the process (b3) in the source gas supply process (B) and the process (c1), the process (c2), and the process (c3) in the reaction gas supply process (C) can be arbitrarily combined and performed. However, in the present invention, the combination of the case where the source gas supply process (B) is the process (b3) and the reaction gas supply process (C) is the process (c3) is excluded.

### EXAMPLES

### Example 1

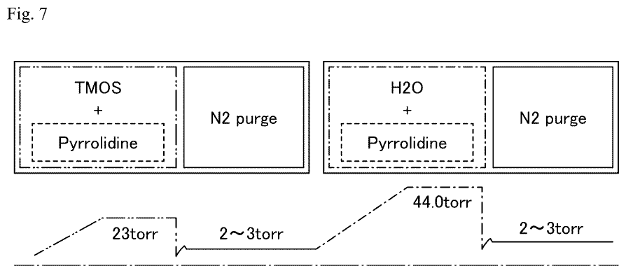

In the present example, a SiO₂ film was formed on the substrate surface on the basis of the film formation sequence for the SiO₂ film shown in FIG. 7 using the film forming device 1 shown in FIG. 1. However, in the film forming device 1, a source gas supply container having an internal volume of 200 ml was used as the source gas supply portion 12, a catalyst gas supply container having an internal volume of 200 ml was used as the first catalyst gas supply portion 13 and the second catalyst gas supply portion, and a reaction gas supply container having an internal volume of 200 ml was used as the reaction gas supply portion 15. In addition, the film forming device 1 was provided with a dry type vacuum pump having an ultimate vacuum degree of 0.1 torr as the vacuum exhaust device for adjusting the pressure in the treatment container 11. Further, a sulfuric acid scrubber and a caustic scrubber were provided in the discharge path 26 in order to remove toxic substances contained in the exhaust gas. Note that FIG. 7 is a diagram illustrating a film formation sequence for a SiO₂ film in Present Example 1. Each process in the present example will be described in detail below.

### (1) Source Gas Supply Process (B)

By using tetrakismethoxysilane (TMOS) gas (manufactured by Shin-Etsu Chemical Co., Ltd., purity: 99.9%) as a source gas and supplying N₂ gas (purity: 99.999%) as a carrier gas to the source gas supply container, a mixture gas in which the TMOS gas is entrained with the N₂ gas was supplied to the treatment container 11. When the TMOS gas was supplied, the temperature in the source gas supply container was set to 30° C., and the pressure was set to 300 torr. In addition, the supply flow rate of the N₂ gas to the source gas supply container was set to 100 sccm. Further, the supply flow rate of the mixture gas including the TMOS gas and the N₂ gas to the treatment container 11 was set to 110 sccm,

In addition, in addition to the supply of the TMOS gas to the treatment container 11, the first catalyst gas was also supplied to the treatment container 11. Pyrrolidine gas (manufactured by Sigma-Aldrich Co., LLC, purity: 99.5%) was used as the first catalyst gas, N₂ gas as a carrier gas was supplied to the catalyst gas supply container to entrain the N₂ gas with the pyrrolidine gas, and a mixture gas including the N₂ gas and the pyrrolidine gas was supplied to the treatment container 11. When the pyrrolidine gas was supplied, the temperature in the catalyst gas supply container was set to 30° C., and the pressure was set to 250 torr. The supply flow rate of the N₂ gas to the catalyst gas supply container was set to 50 sccm. In addition, the supply flow rate of the mixture gas including the pyrrolidine gas and the N₂ gas to the treatment container 11 was set to 80 sccm.

When the mixture gas including the TMOS gas and the N₂ gas and the mixture gas including the pyrrolidine gas and the N₂ gas were simultaneously supplied to the treatment container 11, the temperature in the treatment container 11 was maintained at 80° C., and the pressure in the treatment container 11 was set to 23.3 torr (3.1 kPa). In addition, the supply pressure (film formation pressure) at the time of supplying these mixture gases to the treatment container 11 was set within a range of 25 to 90 torr, and the supply time was set to 60 seconds.

Subsequently, the inside of the treatment container 11 was purged. N₂ gas was used as the first purge gas, and was supplied into the treatment container 11 at a supply flow rate of 500 sccm. In addition, the supply time of the N₂ gas was set to 60 seconds. Further, the pressure in the treatment container 11 was set to 2 to 3 torr.

### (2) Reaction Gas Supply Process (C)

As a reaction gas, H₂O gas obtained by vaporizing pure water (electrical resistivity: 17.5 MΩ·cm) was used, and N₂ gas as a carrier gas was supplied to the reaction gas supply container, so that a mixture gas in which the H₂O gas was entrained with the N₂ gas was supplied to the treatment container 11. When the H₂O gas was supplied, the temperature in the reaction gas supply container was set to 75° C., and the pressure was set to 460 torr. In addition, the supply flow rate of the N₂ gas to the reaction gas supply container was set to 200 sccm. Further, the supply flow rate of the mixture gas including the H₂O gas and the N₂ gas to the treatment container 11 was set to 460 sccm.

In addition, in addition to the supply of the H₂O gas to the treatment container It, the second catalyst gas was also supplied to the treatment container 11. Pyrrolidine gas was used as the second catalyst gas, N₂ gas was supplied to the catalyst gas supply container as in the case of the supply of the first catalyst gas in the source gas supply process (B), to entrain the N₂ gas with the pyrrolidine gas, and a mixture gas including the N₂ gas and the pyrrolidine gas was supplied to the treatment container 11. When the pyrrolidine gas was supplied, the temperature in the catalyst gas supply container was set to 30° C., and the pressure was set to 250 torr. The supply flow rate of the N₂ gas to the first catalyst gas supply container was set to 50 sccm. In addition, the supply flow rate of the mixture gas including the pyrrolidine gas and the N₂ gas to the treatment container 11 was set to 80 sccm.

When the mixture gas including the H₂O gas and the N₂ gas and the mixture gas including the pyrrolidine gas and the N₂ gas were simultaneously supplied to the treatment container 11, the temperature in the treatment container 11 was maintained at 80° C., and the pressure in the treatment container 11 was set to 43.5 torr (5.8 kPa). In addition, the supply pressure (film formation pressure) at the time of supplying these mixture gases to the treatment container 11 was set within a range of 25 to 90 torr, and the supply time was set to 60 seconds.

Subsequently, the inside of the treatment container 11 was purged. N₂ gas was used as the second purge gas, and was supplied into the treatment container 11 at a supply flow rate of 500 sccm. In addition, the supply time of the N₂ gas was set to 90 seconds. Further, the pressure in the treatment container 11 was set to 2 to 3 tot.

### (3) Results

The two processes of the source gas supply process (B) and the reaction gas supply process (C) were set as one cycle, and a total of 400 cycles were performed to form a SiO₂ film on the substrate surface. The formed SiO₂ film had a film density of 2.1 g/cm³, a film thickness of 52.9 nm, and a surface roughness of 0.2 nm. In addition, the film formation rate of the SiO₂ film was 0.13 nm/cycle.

### Example 2

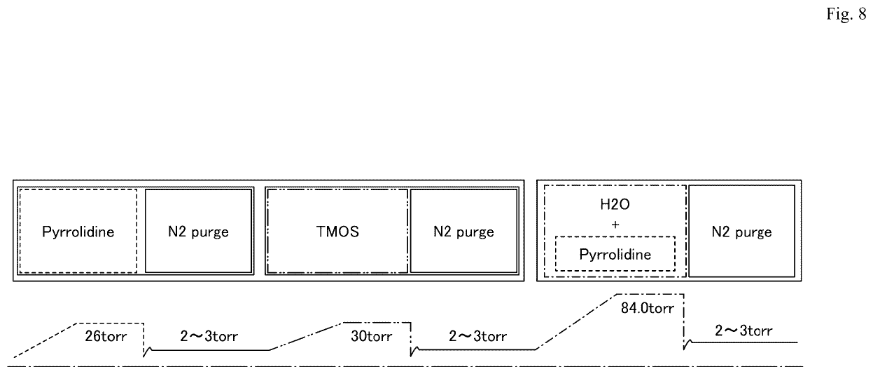

In the present example, a SiO₂ film was formed on the substrate surface on the basis of the film formation sequence for the SiO₂ film shown in FIG. 8 using the film forming device 1 used in Example 1. FIG. 8 is a diagram illustrating a film formation sequence for a SiO₂ film in Present Example 2. Each process in the present example will be described in detail below.

### (I) Source Gas Supply Process (B)

First, a pyrrolidine gas as the first catalyst gas was supplied to the treatment container 11. When the pyrrolidine gas was supplied, the temperature in the first catalyst gas supply container was set to 30° C., and the pressure was set to 250 torr. The supply flow rate of the N₂ gas to the first catalyst gas supply container was set to 50 sccm. In addition, the supply flow rate of the mixture gas including the pyrrolidine gas and the N₂ gas to the treatment container 11 was set to 80 sccm.

In addition, when the mixture gas including the pyrrolidine gas and the N₂ gas was supplied to the treatment container 11, the temperature in the treatment container 11 was maintained at 80° C., and the pressure in the treatment container 11 was set to 26.3 torr (3.5 kPa). In addition, the supply pressure (film formation pressure) at the time of supplying the mixture gas to the treatment container 11 was set within a range of 25 to 90 torr, and the supply time was set to 60 seconds.

Subsequently, the inside of the treatment container 11 was purged. N₂ gas was used as the third purge gas, and was supplied into the treatment container i at a supply flow rate of 500 sccm. In addition, the supply time of the N₂ gas was set to 90 seconds. Further, the pressure in the treatment container 11 was set to 2 to 3 torr.

Next, a TMOS gas as the source gas was supplied to the treatment container 11. When the TMOS gas was supplied, the temperature in the source gas supply container was set to 30° C., and the pressure was set to 300 torr. In addition, the supply how rate of the N₂ gas to the source gas supply container was set to 100 sccm. Further, the supply flow rate of the mixture gas including the TMOS gas and the N₂ gas to the treatment container 11 was set to 10 sccm.

In addition, when the mixture gas including the TMOS gas and the N₂ gas was supplied to the treatment container 11, the temperature in the treatment container 11 was maintained at 80° C., and the pressure in the treatment container 11 was set to 30 torr (4.00 kPa). Further, the supply pressure (film formation pressure) at the time of supplying the mixture gas to the treatment container 11 was set within a range of 25 to 90 torr, and the supply time was set to 60 seconds.

Subsequently, the inside of the treatment container 11 was purged. N₂ gas was used as the first purge gas, and was supplied into the treatment container 11 at a supply flow rate of 500 sccm. In addition, the supply time of the N₂ gas was set to 60 seconds. Further, the pressure in the treatment container 11 was set to 2 to 3 torr.

### (2) Reaction Gas Supply Process (C)

For the reaction gas supply process (C), the pressure in the treatment container was changed from 43.5 torr (5.8 kPa) to 83.3 tor (11.1 kPa). Other than that, the reaction gas supply process (C) was performed in the same manner as in Example 1.

### (3) Results

The two processes of the source gas supply process (B) and the reaction gas supply process (C) were set as one cycle, and a total of 400 cycles were performed to form a SiO₂ film on the substrate surface. The formed SiO₂ film had a film density of 2.2 g/cm³, a film thickness of 32.6 nm, and a surface roughness of 0.2 nm. In addition, the film formation rate of the SiO₂ film was 0.08 nm/cycle.

### Example 3

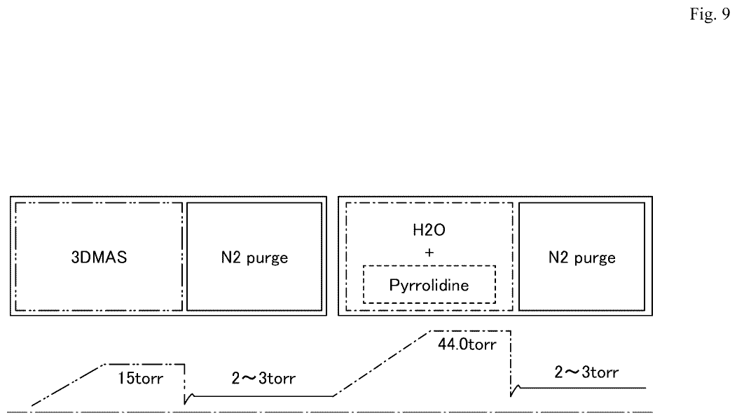

In the present example, a SiO₂ film was formed on the substrate surface on the basis of the film formation sequence for the SiO₂ film shown in FIG. 9 using the film forming device 1 used in Example 1. FIG. 9 is a diagram illustrating a film formation sequence for a SiO₂ film in Present Example 3. Each process in the present example will be described in detail below.

### (1) Source Gas Supply Process (B)

As the source gas, tris(dimethylamino)silane (3DMAS) gas (manufactured by Tri Chemical Laboratories Inc., purity: 99.9%) was used. N₂ gas as a carrier gas was supplied to the source gas supply container, and a mixture gas in which the 3DMAS gas was entrained with the N₂ gas was supplied to the treatment container 11. When the 3DMAS gas was supplied, the temperature in the source gas supply container was set to 27° C., and the pressure was set to 680 torr. In addition, the supply flow rate of the N₂ gas to the source gas supply container was set to 100 sccm. Further, the supply flow rate of the mixture gas including the 3DMAS gas and the N₂ gas to the treatment container 11 was set to 101 sccm.

In addition, when the mixture gas including the 3DMAS gas and the Na gas was supplied to the treatment container 11, the temperature in the treatment container 11 was maintained at 80° C., and the pressure in the treatment container 11 was set to 14.3 torr (1.9 kPa). In addition, the supply pressure (film formation pressure) at the time of supplying the mixture gas to the treatment container 11 was set within a range of 1 torr, and the supply time was set to 12 seconds.

Subsequently, the inside of the treatment container 11 was purged. N₂ gas was used as the first purge gas, and was supplied into the treatment container 11 at a supply flow rate of 500 sccm. In addition, the supply time of the N₂ gas was set to 60 seconds. Further, the pressure in the treatment container 11 was set to 2 to 3 torr.

### (2) Reaction Gas Supply Process (C)

For the reaction gas supply process (C), the pressure in the treatment container was changed from 43.5 torr (5.8 kPa) to 42.0 torr (5.6 kPa). Those other than the above are the same as in Example 1.

### (3) Results

The two processes of the source gas supply process (B) and the reaction gas supply process (C) were set as one cycle, and a total of 400 cycles were performed to form a SiO₂ film on the substrate surface. The formed SiO₂ film had a film density of 2.2 g/cm³, a film thickness of 35.2 nm, and a surface roughness of 0.2 nm. In addition, the film formation rate of the SiO₂ film was 0.088 nm/cycle.

### Example 4

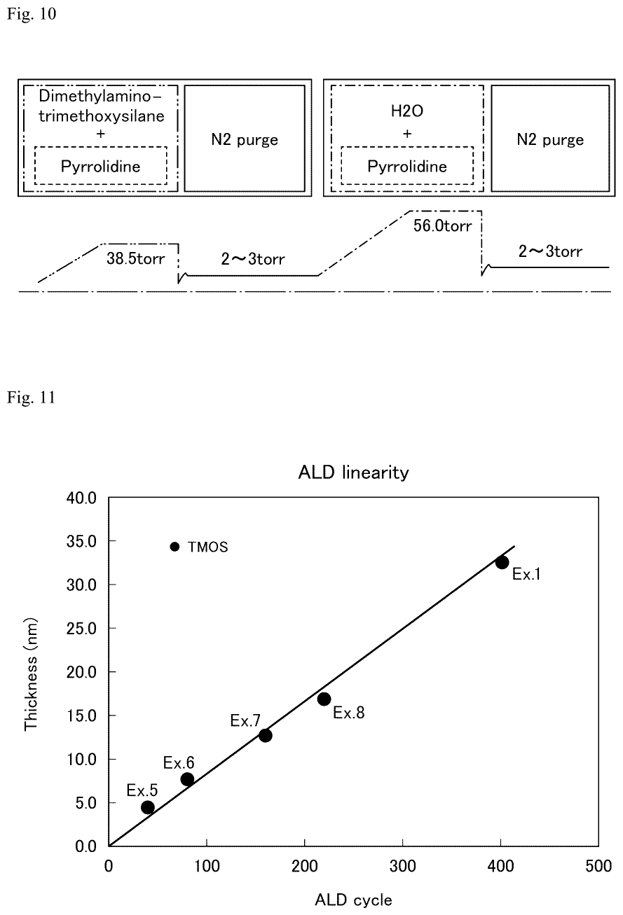

In the present example, a SiO₂ film was formed on the substrate surface on the basis of the film formation sequence for the SiO₂ film shown in FIG. 10 using the film forming device 1 used in Example 1. FIG. 10 is a diagram illustrating a film formation sequence for a SiO₂ film in Present Example 4. Each process in the present example will be described in detail below.

### (1) Source Gas Supply Process (B)

As the source gas, dimethylaminotrimethoxysilane was used. N₂ gas as a carrier gas was supplied to the source gas supply container, and a mixture gas in which dimethylaminotrimethoxysilane was entrained with the N₂ gas was supplied to the treatment container 11. When dimethylaminotrimethoxysilane was supplied, the temperature in the source gas supply container was set to 27° C., and the pressure was set to 385 torr. In addition, the supply flow rate of the N₂ gas to the source gas supply container was set to 100 sccm. Further, the supply flow rate of the mixture gas including dimethylaminotrimethoxysilane and the N₂ gas to the treatment container 11 was set to 102 sccm.

In addition, when dimethylaminotrimethoxysilane was supplied to the treatment container 11, the temperature in the treatment container 11 was maintained at 80° C., and the pressure in the treatment container 11 was set to 1 torr (0.17 kPa). Further, the supply pressure (film formation pressure) at the time of supplying the mixture gas to the treatment container 11 was set within a range of 2 to 3 torr, and the supply time was set to 20 seconds.

Subsequently, the inside of the treatment container 11 was purged. N₂ gas was used as the first purge gas, and was supplied into the treatment container 111 at a supply flow rate of 500 sccm. In addition, the supply time of the N₂ gas was set to 60 seconds. Further, the pressure in the treatment container 11 was set to 2 to 3 torr.

### (2) Reaction Gas Supply Process (C)

In the reaction gas supply process (C), the supply time of the mixture gas including the H₂O gas and the N₂ gas and the mixture gas including the pyrrolidine gas and the N₂ gas was changed to 30 seconds, and the pressure in the treatment container was changed from 43.5 torr (5.8 kPa) to 48.8 torr (6.5 kPa). Other than that, the reaction gas supply process (C) was performed in the same manner as in Example 1.

### (3) Results

The two processes of the source gas supply process (B) and the reaction gas supply process (C) were set as one cycle, and a total of 400 cycles were performed to form a SiO₂ film on the substrate surface. The formed SiO₂ film had a film density of 2.2 g/cm³ a film thickness of 46.6 nm, and a surface roughness of 0.2 nm. In addition, the film formation rate of the SiO₂ film was 0.12 nm/cycle.

### Examples 5 to 8

In Examples 5 to 8, the numbers of cycles of the source gas supply process (B) and the reaction gas supply process (C) were changed to 40 cycles, 80 cycles, 160 cycles, and 220 cycles, respectively. Other than that, a SiO₂ film was formed on the substrate in the same manner as in Example 2. Physical property values of the SiO₂ films obtained in the Examples are indicated in Table 1.

### (Result 1)

As can be seen from Examples 1 to 4, even when the source gas supply process (B) and the reaction gas supply process (C) were performed at a low temperature of 80° C., a SiO₂ film having a high film density and a favorable film quality was formed on the substrate.

In addition, in Examples 1 and 5 to 8, as a result of examining the relationship between the number of cycles and the film thickness, as shown in FIG. 11, it was confirmed that the number of cycles and the film thickness of the SIO₂ film were in a proportional relationship, and an ideal film was formed. Note that FIG. 11 is a graph illustrating a correlation between the number of cycles and the film thickness of a SiO₂ film in a case where a TMOS gas is used as a source gas.

TABLE 1

| | Source gas supply process | | | | | |
|---|---|---|---|---|---|---|
| | | | Temperature | Pressure in | Reaction gas supply process | |
| | | First | of treatment | treatment | | Second |
| | Source | catalyst | container | container | Reaction | catalyst |
| | gas | gas | (° C.) | (kPa) | gas | gas |
| Example 1 | TMOS | Pyrrolidine | 80 | 3.1 | H₂O | Pyrrolidine |
| Example 2 | TMOS | Pyrrolidine | 80 | 3.5, 4.0 | H₂O | Pyrrolidine |
| Example 3 | 3DMAS | — | 80 | 1.9 | H₂O | Pyrrolidine |
| Example 4 | Si(NMe₂)(OMe)₃ | — | 80 | 0.17 | H₂O | Pyrrolidine |
| Example 5 | TMOS | Pyrrolidine | 80 | 3.5, 4.0 | H₂O | Pyrrolidine |
| Example 6 | TMOS | Pyrrolidine | 80 | 3.5, 4.0 | H₂O | Pyrrolidine |
| Example 7 | TMOS | Pyrrolidine | 80 | 3.5, 4.0 | H₂O | Pyrrolidine |
| Example 8 | TMOS | Pyrrolidine | 80 | 3.5, 4.0 | H₂O | Pyrrolidine |

| | Reaction gas supply process | | | | | | |
|---|---|---|---|---|---|---|---|
| | Temperature | Pressure in | | | | | Film |
| | of treatment | treatment | Number | Film | Film | Surface | formation |
| | container | container | of | density | thickness | roughness | rate |
| | (° C.) | (kPa) | cycles | (g/cm²) | (nm) | (nm) | (nm/cycle) |
| Example 1 | 80 | 5.8 | 400 | 2.1 | 52.9 | 0.2 | 0.13 |
| Example 2 | 80 | 11.1 | 400 | 2.2 | 32.6 | 0.2 | 0.08 |
| Example 3 | 80 | 5.6 | 400 | 2.2 | 35.2 | 0.2 | 0.088 |
| Example 4 | 80 | 6.5 | 400 | 2.2 | 46.6 | 0.2 | 0.12 |
| Example 5 | 80 | 11.1 | 40 | 2.1 | 4.5 | 0.4 | 0.11 |
| Example 6 | 80 | 11.1 | 80 | 2.2 | 7.8 | 0.3 | 0.10 |
| Example 7 | 80 | 11.1 | 160 | 2.2 | 12.7 | 0.3 | 0.08 |
| Example 8 | 80 | 11.1 | 220 | 2.3 | 16.9 | 0.3 | 0.08 |

### Example 9

In the present example, a SiO₂ film was formed on the substrate surface using the film forming device 1 used in Example L. More specifically, it was performed as described below.

### (1) Source Gas Supply Process (B)

First, a pyrrolidine gas as the first catalyst gas was supplied to the treatment container 11. When the pyrrolidine gas was supplied, the temperature in the first catalyst gas supply container was set to 30° C., and the pressure was set to 250 torr. The supply flow rate of the N₂ gas to the first catalyst gas supply container was set to 50 sccm. In addition, the supply flow rate of the mixture gas including the pyrrolidine gas and the N₂ gas to the treatment container 11 was set to 80 sccm.

In addition, when the mixture gas including the pyrrolidine gas and the N₂ gas was supplied to the treatment container 11, the temperature in the treatment container 11 was maintained at 50° C., and the pressure in the treatment container 11 was set to 26.3 torr (3.5 kPa), In addition, the supply pressure (film formation pressure) at the time of supplying the mixture gas to the treatment container 11 was set within a range of 25 to 90 torr, and the supply time was set to 60 seconds.

Subsequently, the inside of the treatment container 11 was purged. N₂ gas was used as the third purge gas, and was supplied into the treatment container 11 at a supply flow rate of 300 sccm. In addition, the supply time of the N₂ gas was set to 90 seconds. Further, the pressure in the treatment container 11 was set to 2 to 3 torr.

Next, a TMOS gas as the source gas was supplied to the treatment container 11. When the TMOS gas was supplied, the temperature in the source gas supply container was 30° C., and the pressure was 272 torr. In addition, the supply flow rate of the N₂ gas to the source gas supply container was set to 100 sccm. Further, the supply flow rate of the mixture gas including the TMOS gas and the N₂ gas to the treatment container 11 was set to 10 sccm.

In addition, when the mixture gas including the TMOS gas and the N₂ gas was supplied to the treatment container 11, the temperature in the treatment container 11 was maintained at 50° C., and the pressure in the treatment container 11 was set to 30.0 torr (4.0 kPa). Further, the supply pressure (film formation pressure) at the time of supplying the mixture gas to the treatment container 11 was set within a range of 25 to 90 torr, and the supply time was set to 60 seconds.

Subsequently, the inside of the treatment container 11 was purged. N₂ gas was used as the first purge gas, and was supplied into the treatment container 11 at a supply flow rate of 500 sccm, in addition, the supply time of the N₂ gas was set to 60 seconds. Further, the pressure in the treatment container 11 was set to 2 to 3 torr.

### (2) Reaction Gas Supply Process (C)

For the reaction gas supply process (C), the temperature (film formation temperature) in the treatment container 11 was changed from 80° C. to 50° C., and the pressure in the treatment container 11 was changed from 43.5 torr (5.8 kPa) to 82.5 torr (11.0 kPa). Other than that, the reaction gas supply process (C) was performed in the same manner as in Example 1.

### (3) Results

The two processes of the source gas supply process (B) and the reaction gas supply process (C) were set as one cycle, and a total of 80 cycles were performed to form a SiO₂ film on the substrate surface. Physical property values of the formed SiO₂ films are indicated in Table 2.

### Examples 10 and 11

In Example 10, the pressure in the treatment container 11 in the reaction gas supply process (C) was changed from 83.3 torr (11.1 kPa) to 82.5 torr (11.0 kPa), and in Example 11, the temperature (film formation temperature) in the treatment container 11 in the source gas supply process (B) and the reaction gas supply process (C) was changed from 50° C. to 175° C. Other than that, a SiO₂ film was formed in each case on the substrate in the same manner as in Example 9. Physical property values of the formed SiO₂ films are indicated in Table 2.

### Comparative Example 1

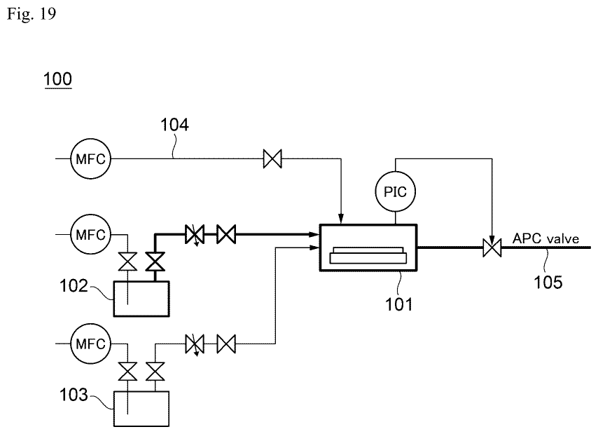

In the present comparative example, a SiO₂ film was formed on the substrate surface using a film forming device 100 shown in FIG. 19. The film forming device 100 shown in FIG. 19 includes a source gas supply container 102 (internal volume: 200 ml) for supplying a source gas to a treatment container 101, a catalyst gas supply container 103 (internal volume: 200 ml) for supplying a catalyst gas to the treatment container 101, a purge gas supply path 104 for supplying a purge gas to the treatment container 101, and a discharge path 105 for discharging an atmosphere in the treatment container 101. In addition, the film forming device 100 was provided with a dry type vacuum pump having an ultimate vacuum degree of 0.1 torr as the vacuum exhaust device for adjusting the pressure in the treatment container 101. Further, a sulfuric acid scrubber and a caustic scrubber were provided in the discharge path 105 in order to remove toxic substances contained in the exhaust gas. Each process in the present comparative example will be described in detail below.

### (1) Source Gas Supply Process

A TMOS gas as the source gas was supplied to the treatment container 101. When the TMOS gas was supplied, the temperature in the source gas supply container 102 was set to 30° C., and the pressure was set to 272 torr. In addition, the supply flow rate of the N₂ gas to the source gas supply container 102 was set to 100 sccm. Further, the supply flow rate of the mixture gas including the TMOS gas and the N₂ gas to the treatment container 101 was set to 110 sccm.

In addition, when the mixture gas including the TMOS gas and the N₂ gas was supplied to the treatment container 101, the temperature in the treatment container 101 was maintained at 50° C., and the pressure in the treatment container 101 was set to 1 torr (13 kPa). Further, the supply pressure (film formation pressure) at the time of supplying the mixture gas to the treatment container 101 was set within a range of 25 to 90 torr, and the supply time was set to 60 seconds.

Subsequently, the inside of the treatment container 101 was purged. N₂ gas was used as the purge gas, and was supplied into the treatment container 101 at a supply flow rate of 500 sccm. In addition, the supply time of the N₂ gas was set to 60 seconds. Further, the pressure in the treatment container 101 was set to 2 to 3 torr.

### (2) Reaction Gas Supply Process

As the reaction gas, ozone gas was used. O₂ gas was supplied to the reaction gas supply container 103, and a part of the O₂ gas was changed to ozone gas in the reaction gas supply container 103, whereby a mixture gas including the ozone gas and the O₂ gas was supplied to the treatment container 101. When the mixture gas was supplied, the temperature in the reaction gas supply container 103 was set to 27° C., and the pressure was set to 0.4 torr. Further, the supply flow rate of the mixture gas including the ozone gas and the O₂ gas to the treatment container 101 was set to 200 sccm.

In addition, when the mixture gas including the ozone gas and the Oy gas was supplied to the treatment container 101, the temperature in the treatment container 101 was maintained at SOT, and the pressure in the treatment container 101 was set to 1.3 kPa. Further, the supply pressure (film formation pressure) at the time of supplying the mixture gas to the treatment container 101 was set within a range of 25 to 90 torr, and the supply time was set to 20 seconds.

Subsequently, the inside of the treatment container 101 was purged. N₂ gas was used as the purge gas, and was supplied into the treatment container 101 at a supply flow rate of 200 sccm. In addition, the supply time of the N₂ gas was set to 12 seconds. Further, the pressure in the treatment container 101 was set to 0.5 torr.

### (3) Results

The two processes of the source gas supply and the reaction gas supply process were set as one cycle, and a total of 80 cycles were performed to form a SiO₂ film on the substrate surface. Physical property values of the formed SiO₂ films are indicated in Table 2.

### Comparative Examples 2 and 3

In Comparative Examples 2 and 3, the temperature (film formation temperature) in the treatment container 101 in the source gas supply process and the reaction gas supply process was changed from 50° C. to 100° C. and 200° C., respectively. Other than that, a SiO₂ film was formed in each case on the substrate in the same manner as in Comparative Example 1. Physical property values of the formed SiO₂ films are indicated in Table 2.

### Comparative Example 4

In the present comparative example, a SiO₂ film was formed on the substrate surface using the film forming device 100 used in Comparative Example 1. More specifically, it was performed as described below.

### (1) Source Gas Supply Process

For the source gas supply process, the temperature (film formation temperature) in the treatment container 101 was changed from 50° C. to 80° C. and the pressure in the treatment container 101 was changed from 43.5 torr (1.3 kPa) to 56.3 torr (7.5 kPa). Other than that, a mixture gas including a TMOS gas and a N₂ gas was supplied to the treatment container 101 in the same manner as in Comparative Example 1.

### (2) Reaction Gas Supply Process

As the reaction gas, H₂O gas was used. N₂ gas as a carrier gas was supplied to the reaction gas supply container 103, and a mixture gas in which the H₂O gas was entrained with the N₂ gas was supplied to the treatment container 101. When the H₂O gas was supplied, the temperature in the reaction gas supply container 103 was set to 30° C., and the pressure was set to 460 torr. In addition, the supply flow rate of the N₂ gas to the reaction gas supply container 103 was set to 200 sccm. Further, the supply flow rate of the mixture gas including the H₂O gas and the N₂ gas to the treatment container 101 was set to 236 sccm.

In addition, when the mixture gas including the H₂O gas and the N₂ gas was supplied to the treatment container 101, the temperature in the treatment container 101 was maintained at 80° C., and the pressure in the treatment container 101 was set to 4 kPa). Further, the supply pressure (film formation pressure) at the time of supplying the mixture gas to the treatment container 101 was set within a range of 25 to 90 torr, and the supply time was set to 60 seconds.

Subsequently, the inside of the treatment container 101 was purged. N₂ gas was used as the purge gas, and was supplied into the treatment container 101 at a supply flow rate of 500 scent. In addition, the supply time of the N₂ gas was set to 60 seconds. Further, the pressure in the treatment container 101 was set to 2 to 3 torr.

### (3) Results

The two processes of the source gas supply and the reaction gas supply process were set as one cycle, and a total of 80 cycles were performed to form a SiO₂ film on the substrate surface, Physical property values of the formed SiO₂ films are indicated in Table 2.

### Comparative Example 5

In Comparative Example 5, the temperature (film formation temperature) in the treatment container 101 in the source gas supply process and the reaction gas supply process was changed from 80° C. to 300° C. Other than that, a SiO₂ film was formed on the substrate in the same manner as in Comparative Example 4. Physical property values of the formed SiO₂ films are indicated in Table 2.

### Comparative Example 6

In the present comparative example, a SiO₂ film was formed on the substrate surface using the film forming device 100 used in Comparative Example 1. More specifically, it was performed as described below.

### (1) Source Gas Supply Process

As the source gas, TMOS gas was used. N₂ gas as a carrier gas was supplied to the source gas supply container 102, and a mixture gas in which the TMOS gas was entrained with the N₂ gas was supplied to the treatment container 101, When the TMOS gas was supplied, the temperature in the source gas supply container 102 was set to 30° C., and the pressure was set to 272 torr. In addition, the supply flow rate of the N₂ gas to the source gas supply container 102 was set to 100 sccm. Further, the supply flow rate of the mixture gas including the TMOS gas and the N₂ gas to the treatment container 101 was set to 110 sccm.

In addition, in addition to the supply of the TMOS gas to the treatment container 101, a catalyst gas was also supplied to the treatment container 101. As the catalyst gas, NH₃ (ammonia) gas was used. The temperature of the NH₃ gas was set to 23° C., and the supply flow rate of the NH: gas to the treatment container 101 was set to 400 sccm.

In addition, when the mixture gas including the TMOS gas and the N₂ gas and the NH: gas were simultaneously supplied to the treatment container 101, the temperature in the treatment container 101 was maintained at 25° C., and the pressure in the treatment container 101 was set to 42 torr (5.6 kPa). Further, the supply pressure (film formation pressure) at the time of supplying these mixture gas to the treatment container 101 was set within a range of 25 to 90 torr, and the supply time was set to 42 seconds.

Subsequently, the inside of the treatment container 101 was purged. N₂ gas was used as the purge gas, and was supplied into the treatment container 101 at a supply flow rate of 200 sccm. In addition, the supply time of the N₂ gas was set to 12 seconds. Further, the pressure in the treatment container 101 was set to 2 to 3 torr,

### (2) Reaction Gas Supply Process

As the reaction gas, H₂O gas was used. Ni gas as a carrier gas was supplied to the reaction gas supply container 103, and a mixture gas in which the H₂O gas was entrained with the N₂ gas was supplied to the treatment container 101. When the H₂O gas was supplied, the temperature in the reaction gas supply container 103 was set to 30° C., and the pressure was set to 42 torr. In addition, the supply flow rate of the N₂ gas to the reaction gas supply container 103 was set to 100 sccm. Further, the supply flow rate of the mixture gas including the H₂O gas and the N₂ gas to the treatment container 101 was set to 114 sccm.

In addition, in addition to the supply of the H₂O gas to the treatment container 101, a catalyst gas was also supplied to the treatment container 101. As the catalyst gas, NH₃ (ammonia)gas was used. The temperature of the NH₃ gas was set to 27° C. and the supply flow rate of the N Hi gas to the treatment container 101 was set to 400 sccm.

In addition, when the mixture gas including the H₂O gas and the N₂ gas and the NH₃ gas were simultaneously supplied to the treatment container 101, the temperature in the treatment container 101 was maintained at 30° C., and the pressure in the treatment container 101 was set to 42 torr (5.6 kPa). Further, the supply pressure (film formation pressure) at the time of supplying these mixture gas to the treatment container 101 was set within a range of 25 to 90 torr, and the supply time was set to 42 seconds.

Subsequently, the inside of the treatment container 101 was purged. N₂ gas was used as the purge gas, and was supplied into the treatment container 101 at a supply flow rate of 200 sccm. In addition, the supply time of the N₂ gas was set to 12 seconds. Further, the pressure in the treatment container 101 was set to 2 to 3 torr,

### (3) Results

The two processes of the source gas supply and the reaction gas supply process were set as one cycle, and a total of 80 cycles were performed to form a SiO₂ film on the substrate surface. Physical property values of the formed SiO₂ films are indicated in Table 2.

### (Result 2)

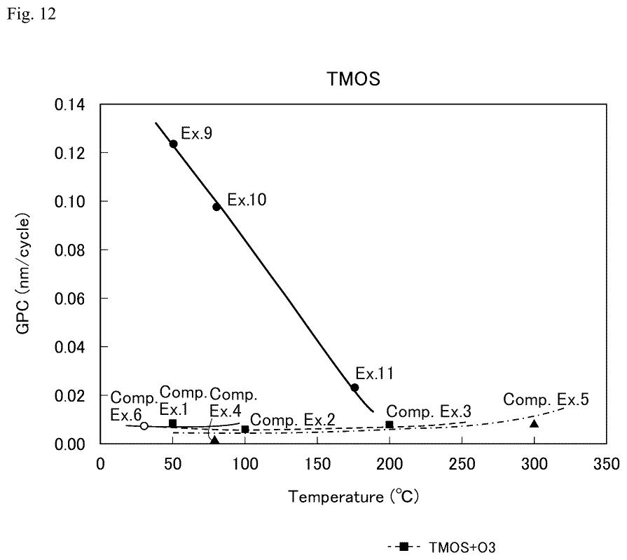

As shown in FIG. 12, by the film forming methods of Examples 9 to 11, even when the source gas supply process (B) and the reaction gas supply process (C) were performed at a low temperature of 175° C. or lower, a SiO₂ film having a high film density and a favorable film quality was formed on the substrate, in particular, in Examples 9 and 10 at 100° C. or lower, a high film formation rate of 008 nm/cycle or more was obtained. On the other hand, by the film forming methods of Comparative Examples 1 to 6, the film formation rate was 0.01 nm/cycle or less at any temperature. Note that FIG. 12 is a graph illustrating a relationship between the temperature in the treatment container and the film formation rate of a SiO₂ film in various film forming methods.

TABLE 2

| | Source gas supply process | | | | Reaction gas supply process | | |
|---|---|---|---|---|---|---|---|
| | | | Temperature | Pressure in | | | Temperature |
| | | First | of treatment | treatment | | Second | of treatment |
| | Source | catalyst | container | container | Reaction | catalyst | container |
| | gas | gas | (° C.) | (kPa) | gas | gas | (° C.) |
| Example 9 | TMOS | Pyrrolidine | 50 | 3.5, 4.0 | H₂O | Pyrrolidine | 50 |
| Example 10 | TMOS | Pyrrolidine | 80 | 3.5, 4.0 | H₂O | Pyrrolidine | 80 |
| Example 11 | TMOS | Pyrrolidine | 175 | 3.5, 4.0 | H₂O | Pyrrolidine | 175 |
| Comparative | TMOS | — | 50 | 1.3 | Ozone | — | 50 |
| Example 1 | | | | | | | |
| Comparative | TMOS | — | 100 | 1.3 | Ozone | — | 100 |
| Example 2 | | | | | | | |
| Comparative | TMOS | — | 200 | 1.3 | Ozone | — | 200 |
| Example 3 | | | | | | | |
| Comparative | TMOS | — | 80 | 7.5 | H₂O | — | 80 |
| Example 4 | | | | | | | |
| Comparative | TMOS | — | 300 | 7.5 | H₂O | — | 300 |
| Example 5 | | | | | | | |
| Comparative | TMOS | NH₃ | 25 | 5.6 | H₂O | NH₃ | 25 |
| Example 6 | | | | | | | |

| | Reaction gas supply process | | | | | |
|---|---|---|---|---|---|---|
| | Pressure in | | | | | Film |
| | treatment | Number | Film | Film | Surface | formation |
| | container | of | density | thickness | roughness | rate |
| | (kPa) | cycles | (g/cm²) | (nm) | (nm) | (nm/cycle) |
| Example 9 | 11.0 | 80 | 2.1 | 9.9 | 0.3 | 0.12 |
| Example 10 | 11.0 | 80 | 2.2 | 7.8 | 0.3 | 0.10 |
| Example 11 | 11.0 | 80 | 2.3 | 1.8 | 0.3 | 0.02 |
| Comparative | 1.3 | 80 | 2.6 | 1.8 | 0.3 | 0.01 |
| Example 1 | | | | | | |
| Comparative | 1.3 | 80 | 2.6 | 1.8 | 0.3 | 0.01 |
| Example 2 | | | | | | |
| Comparative | 1.3 | 80 | 2.7 | 1.8 | 0.3 | 0.01 |
| Example 3 | | | | | | |
| Comparative | 4.0 | 80 | 1.2 | 0.9 | 0.0 | 0.01 |
| Example 4 | | | | | | |
| Comparative | 4.0 | 250 | 2.7 | 1.8 | 0.4 | 0.00 |
| Example 5 | | | | | | |
| Comparative | 5.6 | 80 | 1.2 | 1.1 | 0.3 | 0.01 |
| Example 6 | | | | | | |

### Examples 12 to 14

In each of Examples 12 to 14, the pressure in the treatment container 11 in the source gas supply process (B) was changed from 14.3 torr (19 kPa) to 15.0 torr (2.0 kPa). In addition, the numbers of cycles were changed to 80 cycles, 160 cycles, and 220 cycles, respectively. Other than that, a SiO₂ film was formed on the substrate in the same manner as in Example 3. Physical property values of the SiO₂ films obtained in the Examples are indicated in Table 3.

### (Result 3)

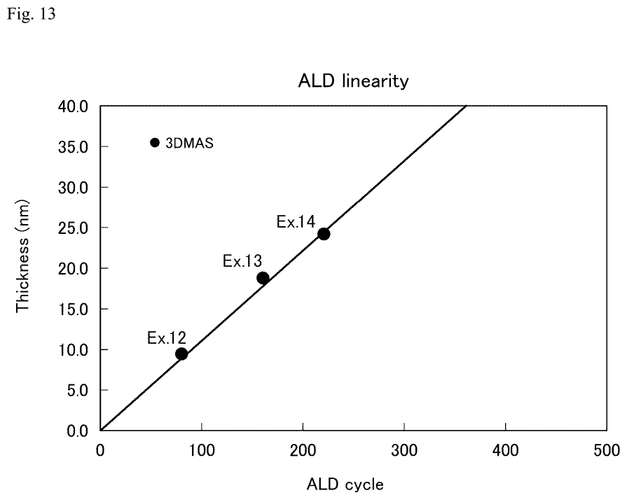

In Examples 12 to 14, as a result of examining the relationship between the number of cycles and the film thickness, also in a case where a 3DMAS gas was used as the source gas, as shown in FIG. 13, it was confirmed that the number of cycles and the film thickness of the SIO₂ film were in a proportional relationship, and an ideal film was formed. Note that FIG. 13 is a graph illustrating a correlation between the number of cycles and the film thickness of a SiO₂ film in a case where a 3DMAS gas is used as a source gas.

TABLE 3

| | Source gas supply process | | | | Reaction gas supply process | | |
|---|---|---|---|---|---|---|---|
| | | | Temperature | Pressure in | | | Temperature |
| | | First | of treatment | treatment | | Second | of treatment |
| | Source | catalyst | container | container | Reaction | catalyst | container |
| | gas | gas | (° C.) | (kPa) | gas | gas | (° C.) |
| Example 6 | 3DMAS | — | 80 | 2.0 | H₂O | Pyrrolidine | 80 |
| Example 6 | 3DMAS | — | 80 | 2.0 | H₂O | Pyrrolidine | 80 |
| Example 6 | 3DMAS | — | 80 | 2.0 | H₂O | Pyrrolidine | 80 |

| | Reaction gas supply process | | | | | |
|---|---|---|---|---|---|---|
| | Pressure in | | | | | Film |
| | treatment | Number | Film | Film | Surface | formation |
| | container | of | density | thickness | roughness | rate |
| | (kPa) | cycles | (g/cm²) | (nm) | (nm) | (nm/cycle) |
| Example 6 | 5.6 | 80 | 2.1 | 9.6 | 0.3 | 0.12 |
| Example 6 | 5.6 | 160 | 2.1 | 18.8 | 0.2 | 0.12 |
| Example 6 | 5.6 | 220 | 2.1 | 24.0 | 0.3 | 0.11 |

### Example 15

In the present example, a SiO₂ film was formed on the substrate surface using the film forming device 1 shown in FIG. 1. More specifically, it was performed as described below.

### (1) Source Gas Supply Process (B)

A 3DMAS gas as the source gas was supplied to the treatment container 11.

When the 3DMAS gas was supplied, the temperature in the source gas supply container was set to 27° C., and the pressure was set to 685 torr. In addition, the supply flow rate of the N₂ gas to the source gas supply container was set to 100 sccm. Further, the supply flow rate of the mixture gas including the 3DMAS gas and the N₂ gas to the treatment container 11 was set to 101 sccm.

In addition, when the mixture gas including the 3DMAS gas and the N₂ gas was supplied to the treatment container 11, the temperature in the treatment container 11 was maintained at 80° C., and the pressure in the treatment container 11 was set to 1 torr (0.17 kPa). In addition, the supply pressure (film formation pressure) at the time of supplying the mixture gas to the treatment container 11 was set within a range of 10 to 90 torr, and the supply time was set to 12 seconds.

Further, the inside of the treatment container 11 was purged. N₂ gas was used as the purge gas, and was supplied into the treatment container 11 at a supply flow rate of 500 sccm. In addition, the supply time of the N₂ gas was set to 60 seconds. Further, the pressure in the treatment container 11 was set to 2 to 3 torr.

### (2) Reaction Gas Supply Process (C)

The reaction gas supply process (C) was performed in the same manner as in Example 1. Accordingly, detailed description thereof will be omitted.

### (3) Results

The two processes of the source gas supply process (B) and the reaction gas supply process (C) were set as one cycle, and a total of 160 cycles were performed to form a SiO₂ film on the substrate surface. Physical property values of the formed SiO₂ films are indicated in Table 4.

### Examples 16 and 17

In Examples 16 and 17, the temperature (film formation temperature) in the treatment container 11 in the source gas supply process (B) and the reaction gas supply process (C) was changed from 80° C. to 125° C., and 175° C., respectively. Other than that, a SiO₂ film was formed in each case on the substrate in the same manner as in Example 15, Physical property values of the SiO₂ films obtained in the Examples are indicated in Table 4.

### Comparative Example 7

In the present comparative example, a SiO₂ film was formed on the substrate surface using the film forming device 100 used in Comparative Example 1. More specifically, it was performed as described below.

### (1) Source Gas Supply Process

A 3DMAS gas as the source gas was supplied to the treatment container 101. When the 3DMAS gas was supplied, the temperature in the source gas supply container 102 was set to 27° C., and the pressure was set to 760 torr. In addition, the supply flow rate of the N₂ gas to the source gas supply container 102 was set to 100 sccm. Further, the supply flow rate of the mixture gas including the 3DMAS gas and the N₂ gas to the treatment container 101 was set to 500 sccm,

In addition, when the mixture gas including the 3DMAS gas and the N₂ gas was supplied to the treatment container 101, the temperature in the treatment container 101 was maintained at 50° C., and the pressure in the treatment container 101 was set to 3.8 torr (0.5 kPa), In addition, the supply pressure (film formation pressure) at the time of supplying the mixture gas to the treatment container 101 was set within a range of 25 to 90 torr, and the supply time was set to 12 seconds.

Further, the inside of the treatment container 101 was purged. N₂ gas was used as the purge gas, and was supplied into the treatment container 101 at a supply flow rate of 500 sccm. In addition, the supply time of the N₂ gas was set to 12 seconds. Further, the pressure in the treatment container 101 was set to 3.4 torr,

### (2) Reaction Gas Supply Process

As the reaction gas ozone gas was used and supplied to the treatment container 101. When the ozone gas was supplied, the temperature in the reaction gas supply container 103 was set to 27° C. In addition, the supply flow rate of the O₂ gas to the reaction gas supply container 103 was set to 200 sccm. Further, the supply flow rate of the mixture gas including the ozone gas and the N₂ gas to the treatment container 101 was set to 200 sccm.

In addition, when the mixture gas including the ozone gas and the O₂ gas was supplied to the treatment container 101, the temperature in the treatment container 101 was maintained at 50° C., and the pressure in the treatment container 101 was set to 3.8 torr (0.5 kPa). Further, the supply pressure (film formation pressure) at the time of supplying the mixture gas to the treatment container 101 was set within a range of 25 to 90 torr, and the supply time was set to 12 seconds.

Subsequently, the inside of the treatment container 101 was purged. N₂ gas was used as the purge gas, and was supplied into the treatment container 101 at a supply flow rate of 500 sccm. In addition, the supply time of the N₂ gas was set to 12 seconds. Further, the pressure in the treatment container 101 was set to 2 to 3 torr,

### (3) Results

The two processes of the source gas supply and the reaction gas supply process were set as one cycle, and a total of 160 cycles were performed to form a SiO₂ film on the substrate surface. Physical property values of the formed SiO₂ films are indicated in Table 4.

### Comparative Examples 8 to 14

In Comparative Examples 8 to 14, the temperature (film formation temperature) and the pressure in the treatment container 101 in the source gas supply process and the reaction gas supply process were changed to values indicated in Table 4. In addition, the number of cycles was also changed to a value indicated in Table 4. Other than that, a SiO₂ film was formed on the substrate in the same manner as in Comparative Example 7. Physical property values of the SiO₂ films obtained in each comparative example are indicated in Table 4.

### Comparative Example 15

In the present comparative example, a SiO₂ film was formed on the substrate surface using the film forming device 100 used in Comparative Example 1. More specifically, it was performed as described below.

### (1) Source Gas Supply Process

The temperature (film formation temperature) in the treatment container 101 was changed from 50° C. to 80° C., and the pressure was changed from 3.8 torr (0.5 kPa) to 15 torr (2.0 kPa). Other than that, a mixture gas including a 3DMAS gas and a N₂ gas was supplied to the treatment container 101 in the same manner as in Comparative Example 7.

(2) Reaction gas supply process

As the reaction gas, H₂O gas was used. N₂ gas as a carrier gas was supplied to the reaction gas supply container 103, and a mixture gas in which the H₂O gas was entrained with the N₂ gas was supplied to the treatment container 101, When the H₂O gas was supplied, the temperature in the reaction gas supply container 103 was set to 75° C., and the pressure was set to 460 torr. In addition, the supply flow rate of the N₂ gas to the reaction gas supply container was set to 200 sccm. Further, the supply flow rate of the mixture gas including the H₂O gas and the N₂ gas to the treatment container 101 was set to 460 sccm.

In addition, when the mixture gas including the H₂O gas and the N₂ gas was supplied to the treatment container 101, the temperature in the treatment container 101 was maintained at 80° C. and the pressure in the treatment container 101 was set to 36 torr (4.8 kPa). Further, the supply pressure (film formation pressure) at the time of supplying the mixture gas to the treatment container 101 was set within a range of 25 to 90 torr, and the supply time was set to 12 seconds.

Subsequently, the inside of the treatment container 101 was purged. N₂ gas was used as the purge gas, and was supplied into the treatment container 101 at a supply flow rate of 500 sccm. In addition, the supply time of the N, gas was set to 12 seconds. Further, the pressure in the treatment container 101 was set to 2 to 3 torr.

### (3) Results

The two processes of the source gas supply and the reaction gas supply process were set as one cycle, and a total of 160 cycles were performed to form a SiO₂ film on the substrate surface. Physical property values of the formed SiO₂ films are indicated in Table 4.

### Comparative Example 16

In Comparative Example 16, the temperature (film formation temperature) in the treatment container 101 in the source gas supply process and the reaction gas supply process was changed from 80° C. to 300° C. Other than that, a SiO₂ film was formed on the substrate in the same manner as in Comparative Example IS. Physical property values of the formed SiO₂ films are indicated in Table 4.

### Comparative Example 17

In the present comparative example, a SiO₂ film was formed on the substrate surface using the film forming device 100 used in Comparative Example 1. More specifically, it was performed as described below.

### (1) Source Gas Supply Process

The temperature (film formation temperature) in the treatment container 101 was changed from 50° C. to 30° C. and the pressure was changed from 3.8 torr (0.5 kPa) to 40.5 torr (5.4 kPa). Other than that, a mixture gas including a 3DMAS gas and a N₂ gas was supplied to the treatment container 101 in the same manner as in Comparative Example 7.

### (2) Reaction Gas Supply Process

As the reaction gas, H₂O gas was used. As the reaction gas supply portion for supplying the H₂O gas, a reaction gas supply container having an internal volume of 200 ml was used, and N₂ gas as a carrier gas was supplied to the reaction gas supply container, so that a mixture gas in which the H₂O gas was entrained with the N₂ gas was supplied to the treatment container 101. When the H₂O gas was supplied, the temperature in the reaction gas supply container was set to 27° C., and the pressure was set to 760 torr. In addition, the supply flow rate of the N₂ gas to the reaction gas supply container was set to 100 sccm. Further, the supply flow rate of the mixture gas including the H₂O gas and the N₂ gas to the treatment container 101 was set to 500 sccm.

In addition, in addition to the supply of the H₂O gas to the treatment container 101, a catalyst gas was also supplied to the treatment container 101. As the catalyst gas. NH₃ (ammonia) gas was used. The temperature of the NH₃ gas was set to 27° C., and the supply flow rate of the NH₃ gas to the treatment container 101 was set to 400 sccm,

When the mixture gas including the H₂O gas and the N₂ gas and the mixture gas including the NH₃ gas and the N₂ gas were simultaneously supplied to the treatment container 101, the temperature in the treatment container 101 was maintained at 30° C., and the pressure in the treatment container 101 was set to 40.5 torr (5.4 kPa). In addition, the supply pressure (film formation pressure) at the time of supplying these mixture gases to the treatment container 101 was set within a range of 25 to 90 torr, and the supply time was set to 42 seconds.

Further, the inside of the treatment container 101 was purged. NH₃ gas was used as the purge gas, and was supplied into the treatment container 101 at a supply flow rate of 400 sccm. In addition, the supply time of the NH₃ gas was 12 seconds. Further, the pressure in the treatment container 101 was 30.5 torr (4.1 kPa).

### (3) Results

The two processes of the source gas supply and the reaction gas supply process were set as one cycle, and a total of 200 cycles were performed to form a SiO₂ film on the substrate surface. Physical property values of the formed SiO₂ films are indicated in Table 4.

### Comparative Example 18

In Comparative Example 18, the pressure in the treatment container 101 in the source gas supply process and the reaction gas supply process was changed from 15 torr (2.0 kPa) to 40.5 torr (54 kPa). In addition, the number of cycles was changed from 160 to 40. Other than that, a SiO₂ film was formed on the substrate in the same manner as in Comparative Example 15. Physical property values of the formed SiO₂ films are indicated in Table 4.

### (Result 4)

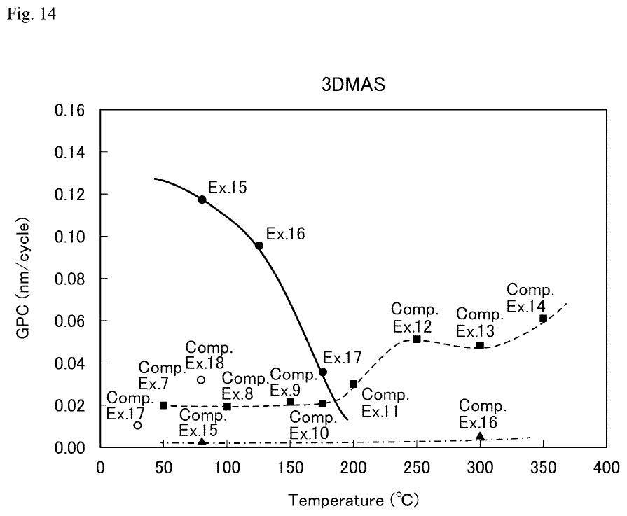

As shown in FIG. 14, by the film forming methods of Examples 15 to 17, even when the source gas supply process (B) and the reaction gas supply process (C) were performed at a low temperature of 175° C. or lower, it was confirmed that a SiO₂ film having a favorable film quality was formed on the substrate. In particular, in Example 15 at 100° C. or lower, a high film formation rate of 0.10 nm/cycle or more was obtained. On the other hand, by the film forming methods of Comparative Examples 7 to 18, the film formation rate at a low temperature of 200° C. or lower was 0.03 nm/cycle or less, and it was confirmed that the film forming methods were not suitable for film formation in a low-temperature region. Note that FIG. 14 is a graph illustrating a relationship between the temperature in the treatment container and the film formation rate of a SiO₂ film in various film forming methods.

TABLE 4

| | Source gas supply process | | | | Reaction gas supply process | | |
|---|---|---|---|---|---|---|---|
| | | | Temperature | Pressure in | | | Temperature |
| | | First | of treatment | treatment | | Second | of treatment |
| | Source | catalyst | container | container | Reaction | catalyst | container |
| | gas | gas | (° C.) | (kPa) | gas | gas | (° C.) |
| Example 15 | 3DMAS | — | 80 | 2.0 | H₂O | Pyrrolidine | 80 |
| Example 16 | 3DMAS | — | 125 | 2.0 | H₂O | Pyrrolidine | 125 |
| Example 17 | 3DMAS | — | 175 | 2.0 | H₂O | Pyrrolidine | 175 |
| Comparative | 3DMAS | — | 50 | 0.5 | Ozone | — | 50 |
| Example 7 | | | | | | | |
| Comparative | 3DMAS | — | 100 | 0.5 | Ozone | — | 100 |
| Example 8 | | | | | | | |
| Comparative | 3DMAS | — | 150 | 0.0 | Ozone | — | 150 |
| Example 9 | | | | | | | |
| Comparative | 3DMAS | — | 175 | 0.0 | Ozone | — | 175 |
| Example 10 | | | | | | | |
| Comparative | 3DMAS | — | 200 | | Ozone | — | 200 |
| Example 11 | | | | | | | |
| Comparative | 3DMAS | — | 250 | | Ozone | — | 250 |
| Example 12 | | | | | | | |
| Comparative | 3DMAS | — | 300 | 0.0 | Ozone | — | 300 |
| Example 13 | | | | | | | |
| Comparative | 3DMAS | — | 350 | | Ozone | — | 350 |
| Example 14 | | | | | | | |
| Comparative | 3DMAS | — | 80 | 2.0 | H₂O | — | 80 |
| Example 15 | | | | | | | |
| Comparative | 3DMAS | — | 300 | 2.0 | H₂O | — | 300 |
| Example 16 | | | | | | | |
| Comparative | 3DMAS | — | 30 | 5.4 | H₂O | NH₃ | 30 |
| Example 17 | | | | | | | |
| Comparative | 3DMAS | — | 80 | 5.4 | H₂O | NH₃ | 80 |
| Example 18 | | | | | | | |

| | Reaction gas supply process | | | | | |
|---|---|---|---|---|---|---|
| | Pressure in | | | | | Film |
| | treatment | Number | Film | Film | Surface | formation |
| | container | of | density | thickness | roughness | rate |
| | (kPa) | cycles | (g/cm²) | (nm) | (nm) | (nm/cycle) |
| Example 15 | 5.6 | 160 | 2.1 | 18.8 | 0.2 | 0.12 |
| Example 16 | 5.6 | 160 | 2.2 | 15.2 | 0.1 | 0.09 |
| Example 17 | 5.6 | 160 | 2.2 | 5.6 | 0.4 | 0.04 |
| Comparative | 0.5 | 490 | 2.2 | 9.6 | 0.3 | 0.02 |
| Example 7 | | | | | | |
| Comparative | 0.5 | 250 | 2.2 | 4.7 | 0.3 | 0.02 |
| Example 8 | | | | | | |
| Comparative | 0.1 | 1000 | 2.2 | 20.4 | 0.5 | 0.02 |
| Example 9 | | | | | | |
| Comparative | 0.1 | 1000 | 2.2 | 20.3 | 0.7 | 0.02 |
| Example 10 | | | | | | |
| Comparative | 0.1 | 160 | 2.1 | 4.8 | 0.4 | 0.03 |
| Example 11 | | | | | | |
| Comparative | 0.1 | 160 | 2.1 | 7.7 | 0.5 | 0.05 |
| Example 12 | | | | | | |
| Comparative | 0.0 | 105 | 2.1 | 5.0 | 0.4 | 0.05 |
| Example 13 | | | | | | |
| Comparative | 0.1 | 160 | 2.2 | 9.6 | 0.6 | 0.06 |
| Example 14 | | | | | | |
| Comparative | 4.8 | 160 | 1.2 | 1.1 | 0.3 | 0.01 |
| Example 15 | | | | | | |
| Comparative | 4.8 | 160 | 1.3 | 0.6 | 0.4 | 0.00 |
| Example 16 | | | | | | |
| Comparative | 5.4 | 200 | 1.4 | 2.0 | 0.9 | 0.01 |
| Example 17 | | | | | | |
| Comparative | 5.4 | 40 | 1.3 | 1.3 | 0.5 | 0.04 |
| Example 18 | | | | | | |

### Example 18

In the present example, a SiO₂ film was formed on the substrate surface using the film forming device 1 used in Example L. More specifically, it was performed as described below.

### (1) Source Gas Supply Process (B)

In the source gas supply process (B), 1,1,3,3-tetramethylguanidine (TMG) gas was used as the first catalyst gas in place of pyrrolidine gas. In addition, when the mixture gas including the TMOS gas and the N₂ gas and the mixture gas including the TMG gas and the N₂ gas were simultaneously supplied to the treatment container 11, the temperature in the treatment container 11 was maintained at 60° C., the pressure in the treatment container 11 was set to 90 torr(12 kPa), and the supply time was changed to 30 minutes. Other than that, the source gas supply process (B) was performed in the same manner as in Example 1.

### (2) Reaction Gas Supply Process (C)

In the reaction gas supply process (C), TMG gas was used as the second catalyst gas in place of pyrrolidine gas. In addition, when the mixture gas including the H₂O gas and the N₂ gas and the mixture gas including the TMG gas and the N₂ gas were simultaneously supplied to the treatment container 11, the temperature in the treatment container 11 was maintained at 60° C., the pressure in the treatment container 11 was set to 90 torr (12 kPa), and the supply time was changed to 30 minutes. Other than that, the reaction gas supply process (C) was performed in the same manner as in Example 1.

### (3) Results

The source gas supply process (B) and the reaction gas supply process (C) were performed to form a SiO₂ film on the substrate surface. The formed SiO₂ film had a film density of 1.7 g/cm³, a film thickness of 6.9 nm, and a surface roughness of 0.8 nm. In addition, the film formation rate of the SiO₂ film was 0.23 nm/cycle.

### Examples 19 to 22

In Examples 19 to 22, the temperature in the treatment container 11 in the source gas supply process (B) and the reaction gas supply process (C) was changed to 80° C. in Example 19, 100° C. in Example 20, 140° C. in Example 21, and 175° C. in Example 22. Other than that, a SiO₂ film was formed in each case on the substrate in the same manner as in Example 18. Physical property values of the formed SiO₂ films are indicated in Table 5.

### Examples 23 to 28

In Examples 23 to 28, pyrrolidine gas was used as the first catalyst gas and the second catalyst gas in place of TMG gas. In addition, the pressure in the treatment container 11 in the source gas supply process (B) and the reaction gas supply process (C) was changed to 60 torr (8 kPa). In addition, the temperature in the treatment container 11 in the source gas supply process (B) and the reaction gas supply process (C) was changed to 80° C. in Example 24, 100° C. in Example 25, 120° C. in Example 26, 200° C. in Example 27, and 250° C. in Example 28. Other than that, a SiO₂ film was formed in each case on the substrate in the same manner as in Example 18. Physical property values of the formed SiO₂ films are indicated in Table 5.

### Comparative Examples 19 to 22

In Comparative Examples 19 to 22, pyridine gas was used as the first catalyst gas and the second catalyst gas in place of TMG gas, in addition, the temperature in the treatment container 101 in the source gas supply process (B) and the reaction gas supply process (C) was changed to 80° C. in Comparative Example 19, 100° C. in Comparative Example 20, 120° C. in Comparative Example 21, and 150° C. in Comparative Example 22. Other than that, a SiO₂ film was formed in each case on the substrate in the same manner as in Example 18. Physical property values of the formed SiO₂ films are indicated in Table 5.

### (Result 5)

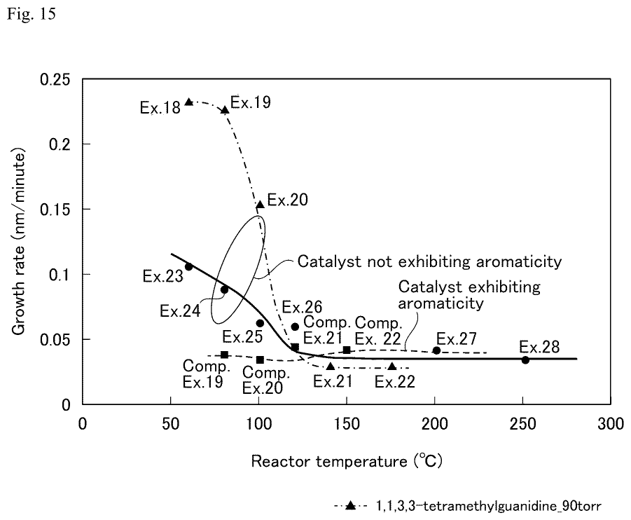

As shown in FIG. 15, in Examples 18 to 21 and 23 to 26 in which TMG gas or pyrrolidine gas having no aromaticity was used as the first catalyst gas and the second catalyst gas, it was confirmed that the film formation rate of the SiO₂ film was increased and the SiO₂ film was sufficiently formed even in a low-temperature region of about 140° C. or lower. In addition, in Examples 22, 27, and 28, a SiO₂ film having a favorable film quality was obtained. On the other hand, in the case of using a pyridine gas having aromaticity, it was confirmed that the film formation rate of the SiO₂ film was remarkably low even in a low-temperature region and the film formation efficiency was not favorable. Note that FIG. 15 is a graph illustrating a relationship between the temperature in the treatment container and the film formation rate of a SiO₂ film in various film forming methods.

TABLE 5

| | Source gas supply process | | | | | |
|---|---|---|---|---|---|---|
| | | | Temperature | Pressure in | Reaction gas supply process | |
| | | First | of treatment | treatment | | Second |
| | Source | catalyst | container | container | Reaction | catalyst |
| | gas | gas | (° C.) | (kPa) | gas | gas |
| Example 18 | TMOS | 1,1,3,3- | 60 | 12 | H₂O | 1,1,3,3- |
| | | tetramethylguanidine | | | | tetramethylguanidine |
| Example 19 | TMOS | 1,1,3,3- | 80 | 12 | H₂O | 1,1,3,3- |
| | | tetramethylguanidine | | | | tetramethylguanidine |
| Example 20 | TMOS | 1,1,3,3- | 100 | 12 | H₂O | 1,1,3,3- |
| | | tetramethylguanidine | | | | tetramethylguanidine |
| Example 21 | TMOS | 1,1,3,3- | 140 | 12 | H₂O | 1,1,3,3- |
| | | tetramethylguanidine | | | | tetramethylguanidine |
| Example 22 | TMOS | 1,1,3,3- | 175 | 12 | H₂O | 1,1,3,3- |
| | | tetramethylguanidine | | | | tetramethylguanidine |
| Example 23 | TMOS | Pyrrolidine | 60 | 8 | H₂O | Pyrrolidine |
| Example 24 | TMOS | Pyrrolidine | 80 | 8 | H₂O | Pyrrolidine |
| Example 25 | TMOS | Pyrrolidine | 100 | 8 | H₂O | Pyrrolidine |
| Example 26 | TMOS | Pyrrolidine | 120 | 8 | H₂O | Pyrrolidine |
| Example 27 | TMOS | Pyrrolidine | 200 | 8 | H₂O | Pyrrolidine |
| Example 28 | TMOS | Pyrrolidine | 250 | 8 | H₂O | Pyrrolidine |
| Comparative | TMOS | Pyridine | 80 | 12 | H₂O | Pyridine |
| Example 19 | | | | | | |
| Comparative | TMOS | Pyridine | 100 | 12 | H₂O | Pyridine |
| Example 20 | | | | | | |
| Comparative | TMOS | Pyridine | 120 | 12 | H₂O | Pyridine |
| Example 21 | | | | | | |
| Comparative | TMOS | Pyridine | 150 | 12 | H₂O | Pyridine |
| Example 22 | | | | | | |

| | Reaction gas supply process | | | | | | |
|---|---|---|---|---|---|---|---|
| | Temperature | Pressure in | | | | | Film |
| | of treatment | treatment | Number | Film | Film | Surface | formation |
| | container | container | of | density | thickness | roughness | rate |
| | (° C.) | (kPa) | cycles | (g/cm²) | (nm) | (nm) | (nm/cycle) |
| Example 18 | 60 | 12 | 30 | 1.7 | 6.9 | 0.8 | 0.23 |
| Example 19 | 80 | 12 | 30 | 1.6 | 6.7 | 0.7 | 0.22 |
| Example 20 | 100 | 12 | 30 | 1.8 | 4.5 | 1.0 | 0.15 |
| Example 21 | 140 | 12 | 30 | 1.6 | 0.8 | 0.7 | 0.03 |
| Example 22 | 175 | 12 | 30 | 2.3 | 0.8 | 0.8 | 0.03 |
| Example 23 | 60 | 8 | 30 | 1.8 | 3.2 | 0.4 | 0.11 |
| Example 24 | 80 | 8 | 30 | 1.6 | 2.6 | 0.6 | 0.09 |
| Example 25 | 100 | 8 | 30 | 1.8 | 1.9 | 0.5 | 0.06 |
| Example 26 | 120 | 8 | 30 | 1.9 | 1.8 | 0.5 | 0.06 |
| Example 27 | 200 | 8 | 30 | 1.8 | 1.2 | 0.3 | 0.04 |
| Example 28 | 250 | 8 | 30 | 1.7 | 1.0 | 0.2 | 0.03 |
| Comparative | 80 | 12 | 30 | 1.4 | 1.2 | 0.1 | 0.04 |
| Example 19 | | | | | | | |
| Comparative | 100 | 12 | 30 | 1.4 | 1.1 | 0.0 | 0.03 |
| Example 20 | | | | | | | |
| Comparative | 120 | 12 | 30 | 1.7 | 1.4 | 0.0 | 0.04 |
| Example 21 | | | | | | | |
| Comparative | 150 | 12 | 30 | 1.5 | 1.2 | 0.2 | 0.04 |
| Example 22 | | | | | | | |

### Examples 29 to 32

In Examples 29 to 32, the pressure in the treatment container 11 in the source gas supply process (B) and the reaction gas supply process (C) was changed to 30 torr (4 kPa) in Examples 29 and 30, and 202.5 torr (27 kPa) in Example 32. In addition, the temperature in the treatment container 11 in the source gas supply process (B) and the reaction gas supply process (C) was changed in each case to 80° C. Further, the supply time when the mixture gas including the TMOS gas and the N₂ gas, the mixture gas including the reaction gas H₂O and the N₂ gas, and the mixture gas including the TMG gas and the N₂ gas were simultaneously supplied to the treatment container 11 was changed to 30 minutes in Examples 29 and 31, 60 minutes in Example 30, and 15 minutes in Example 32. Other than that, a SiO₂ film was formed in each case on the substrate in the same manner as in Example 18. Physical property values of the formed SiO₂ films are indicated in Table 6.

### Examples 33 to 36

In Examples 33 to 36, pyrrolidine gas was used as the first catalyst gas and the second catalyst gas in place of TMG gas. In addition, the pressure in the treatment container 11 in the source gas supply process (B) and the reaction gas supply process (C) was changed to 0.1 kPa in Example 33, 8 kPa in Example 35, and 16 kPa in Example 36. Other than that, a SiO₂ film was formed in each case on the substrate in the same manner as in Example 29. Physical property values of the formed SiO₂ films are indicated in Table 6.

### Comparative Examples 23 to 27

In Comparative Examples 23 to 27, pyridine gas was used as the first catalyst gas and the second catalyst gas in place of TMG gas. In addition, the pressure in the treatment container 101 in the source gas supply process (B) and the reaction gas supply process (C) was changed to 1.3 kPa in Comparative Example 23, 4.0 kPa in Comparative Example 24, 8.0 kPa in Comparative Example 25, 12.0 kPa in Comparative Example 26, and 26.7 kPa in Comparative Example 27. Other than that, a SiO₂ film was formed in each case on the substrate in the same manner as in Example 29. Physical property values of the formed SiO₂ films are indicated in Table 6.

### Comparative Example 28

In Comparative Example 28. NH₃ gas was used as the first catalyst gas and the second catalyst gas in place of TMG gas, in addition, the pressure in the treatment container 101 in the source gas supply process (B) and the reaction gas supply process (C) was changed to 4.0 kPa. Other than that, a SiO₂ film was formed on the substrate in the same manner as in Example 29. Physical property values of the formed SiO₂ films are indicated in Table 6.

### (Result 6)

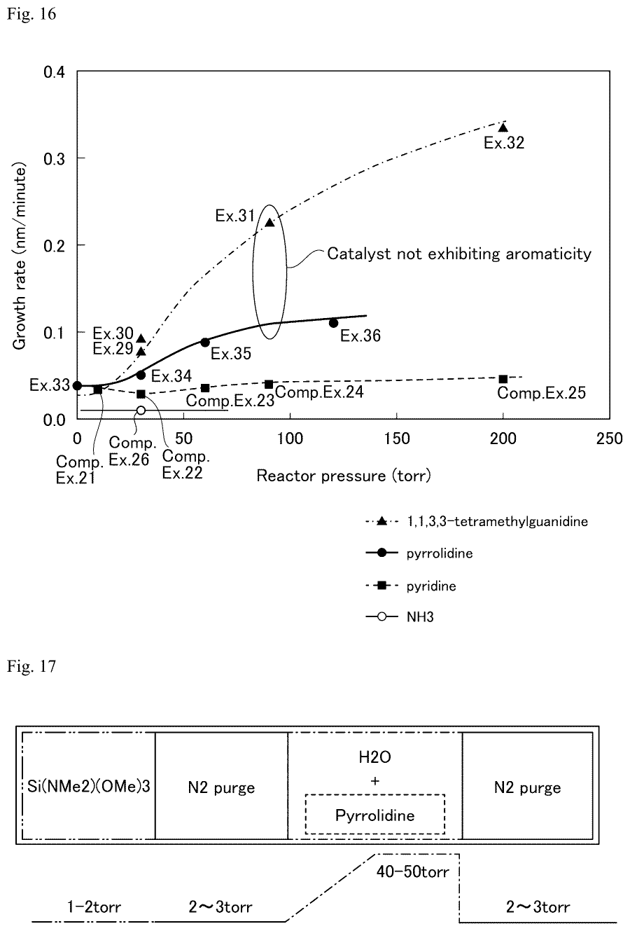

As shown in FIG. 16, in Examples 29 to 32 and 34 to 36 in which the TMG gas having no aromaticity (acid dissociation constant pKa at 25° C. 13.6) or the pyrrolidine gas(acid dissociation constant pKa at 25° C.: 11.3) was used as the first catalyst gas and the second catalyst gas, the film formation rate of a favorable SiO₂ film was exhibited at a pressure of 4.0 kPa or more. In particular, it was confirmed that the TMG gas having a larger pKa value has a higher film formation rate than the pyrrolidine gas, and the film formation efficiency can be improved by using the catalyst gas having a larger pKa value as the non-aromatic amine gas. On the other hand, the film formation rate was remarkably low with the pyridine gas having aromaticity (acid dissociation constant pKa at 25° C.: 5.25), and the SiO₂ film could not be formed with the NH₃ gas. Note that FIG. 16 is a graph illustrating a relationship between the pressure in the treatment container and the film formation rate of a SiO₂ film in various film forming methods.

TABLE 6

| | Source gas supply process | | | | | |
|---|---|---|---|---|---|---|
| | | | Temperature | Pressure in | Reaction gas supply process | |
| | | First | of treatment | treatment | | Second |
| | Source | catalyst | container | container | Reaction | catalyst |
| | gas | gas | (° C.) | (kPa) | gas | gas |
| Example 29 | TMOS | 1,1,3,3- | 80 | 4.0 | H₂O | 1,1,3,3- |
| | | tetramethylguanidine | | | | tetramethylguanidine |
| Example 30 | TMOS | 1,1,3,3- | 80 | 4.0 | H₂O | 1,1,3,3- |
| | | tetramethylguanidine | | | | tetramethylguanidine |
| Example 31 | TMOS | 1,1,3,3- | 80 | 12.0 | H₂O | 1,1,3,3- |
| | | tetramethylguanidine | | | | tetramethylguanidine |
| Example 32 | TMOS | 1,1,3,3- | 80 | 26.7 | H₂O | 1,1,3,3- |
| | | tetramethylguanidine | | | | tetramethylguanidine |
| Example 33 | TMOS | Pyrrolidine | 80 | 0.1 | H₂O | Pyrrolidine |
| Example 34 | TMOS | Pyrrolidine | 80 | 4.0 | H₂O | Pyrrolidine |
| Example 35 | TMOS | Pyrrolidine | 80 | 8.0 | H₂O | Pyrrolidine |
| Example 36 | TMOS | Pyrrolidine | 80 | 16.0 | H₂O | Pyrrolidine |
| Comparative | TMOS | Pyridine | 80 | 1.3 | H₂O | Pyridine |
| Example 23 | | | | | | |
| Comparative | TMOS | Pyridine | 80 | 4.0 | H₂O | Pyridine |
| Example 24 | | | | | | |
| Comparative | TMOS | Pyridine | 80 | 8.0 | H₂O | Pyridine |
| Example 25 | | | | | | |
| Comparative | TMOS | Pyridine | 80 | 12.0 | H₂O | Pyridine |
| Example 26 | | | | | | |
| Comparative | TMOS | Pyridine | 80 | 26.7 | H₂O | Pyridine |
| Example 27 | | | | | | |
| Comparative | TMOS | NH₃ | 80 | 4.0 | H₂O | NH₃ |
| Example 28 | | | | | | |

| | Reaction gas supply process | | | | | | |
|---|---|---|---|---|---|---|---|
| | Temperature | Pressure in | | | | | Film |
| | of treatment | treatment | Number | Film | Film | Surface | formation |
| | container | container | of | density | thickness | roughness | rate |
| | (° C.) | (kPa) | cycles | (g/cm²) | (nm) | (nm) | (λ/min) |
| Example 29 | 80 | 4.0 | 30 | 1.9 | 2.7 | 0.9 | 0.09 |
| Example 30 | 80 | 4.0 | 60 | 1.8 | 4.7 | 1.0 | 0.08 |
| Example 31 | 80 | 12.0 | 30 | 1.6 | 6.7 | 0.7 | 0.22 |
| Example 32 | 80 | 26.7 | 15 | 1.7 | 5.0 | 0.6 | 0.33 |
| Example 33 | 80 | 0.1 | 30 | 1.8 | 1.1 | 0.4 | 0.04 |
| Example 34 | 80 | 4.0 | 30 | 1.7 | 1.5 | 0.4 | 0.05 |
| Example 35 | 80 | 8.0 | 30 | 1.6 | 2.6 | 0.6 | 0.09 |
| Example 36 | 80 | 16.0 | 30 | 1.6 | 3.3 | 0.6 | 0.11 |
| Comparative | 80 | 1.3 | 30 | 1.4 | 1.0 | 0.0 | 0.034 |
| Example 23 | | | | | | | |
| Comparative | 80 | 4.0 | 30 | 1.3 | 0.8 | 0.4 | 0.028 |
| Example 24 | | | | | | | |
| Comparative | 80 | 8.0 | 30 | 1.8 | 1.1 | 0.4 | 0.036 |
| Example 25 | | | | | | | |
| Comparative | 80 | 12.0 | 30 | 1.7 | 1.2 | 0.4 | 0.040 |
| Example 26 | | | | | | | |
| Comparative | 80 | 26.7 | 30 | 1.7 | 1.3 | 0.4 | 0.045 |
| Example 27 | | | | | | | |
| Comparative | 80 | 4.0 | 30 | 1.6 | 5.1 | 0.5 | 0.017 |
| Example 28 | | | | | | | |

### Example 37

In the present example, a SiO₂ film was formed on the substrate surface on the basis of the film formation sequence for the SiO₂ film shown in FIG. 17 using the film forming device 1 shown in FIG. 1L FIG. 17 is a diagram illustrating a film formation sequence for a SiO₂ film in Present Example 37. Each process in the present example will be described in detail below.

### (1) Source Gas Supply Process (B)

As the source gas, Si(NMe₂)(OMe)₃ gas was used. N₂ gas as a carrier gas was supplied to the source gas supply container, and a mixture gas in which the Si(NMe₂)(OMe)₃ gas was entrained with the Na gas was supplied to the treatment container i L When the Si(NMe₂)(OMe)₃ gas was supplied, the temperature in the source gas supply container was set to 27° C., and the pressure was set to 385 torr. In addition, the supply flow rate of the N₂ gas to the source gas supply container was set to 100 sccm. Further, the supply flow rate of the mixture gas including the Si(NMe₂)(OMe) gas and the N₂ gas to the treatment container 11 was set to 102 sccm.

In addition, when the mixture gas including the Si(NMe₂)(OMe)₃ gas and the N₂ gas was supplied to the treatment container 11, the temperature in the treatment container 11 was maintained at 80° C., and the pressure in the treatment container 11 was set to 1 to 2 torr (0.13 kPa to 0.27 kPa). Further, the supply pressure (film formation pressure) at the time of supplying the mixture gas to the treatment container 11 was set within a range of 45 to 50 torr, and the supply time was set to 60 seconds.

Subsequently, the inside of the treatment container 11 was purged. N₂ gas was used as the first purge gas, and was supplied into the treatment container 11 at a supply flow rate of 500 sccm. In addition, the supply time of the N₂ gas was set to 60 seconds. Further, the pressure in the treatment container 11 was set to 2 to 3 torr.

### (2) Reaction Gas Supply Process (C)

In the reaction gas supply process (C), the pressure in the treatment container 11 was set to 40 to 50 torr (5.33 kPa to 6.67 kPa), the supply pressure (film formation pressure) when the mixture gas including the H₂O gas and the N₂ gas and the mixture gas including the pyrrolidine gas and the N₂ gas were simultaneously supplied to the treatment container 11 was set within a range of 45 to 50 torr, and the supply time (pulse time) was set to 12 seconds. Further, the supply flow rate of the N₂ gas at the time of purging the inside of the treatment container 11 using the N₂ gas as the second purge gas was set to 500 sccm. Other than that, a SiO₂ film was formed on the substrate as in the reaction gas supply process (C) of Example 1.

### (3) Results

The two processes of the source gas supply process (B) and the reaction gas supply process (C) were set as one cycle, and a total of 80 cycles were performed to form a SiO₂ film on the substrate surface. Physical property values of the formed SiO₂ films are indicated in Table 7.

### Examples 38 and 39

In Examples 38 and 39, in the reaction gas supply process (C), the supply time (pulse time) when the mixture gas including the H₂O gas and the N₂ gas and the mixture gas including the pyrrolidine gas and the N₂ gas were simultaneously supplied to the treatment container 11 was set to 30 seconds and 60 seconds, respectively. Other than that, a SiO₂ film was formed on the substrate in the same manner as in Example 37.

Further, the two processes of the source gas supply process (B) and the reaction gas supply process (C) were set as one cycle, and a total of 80 cycles were performed in each case to form a SiO₂ film on the substrate surface. Physical property values of the SiO₂ films obtained in the Examples are indicated in Table 7.

### Examples 40 to 42

In Examples 40 to 42, 1-methylpiperidine gas (manufactured by Sigma-Aldrich Co., LLC, purity: 99%) was used as the second catalyst gas in the reaction gas supply process (C). In addition, the supply time (pulse time) when the mixture gas including the H₂O gas and the N₂ gas and the mixture gas including the I-methylpiperidine gas and the N₂ gas were simultaneously supplied to the treatment container 11 was set to 30 seconds, 60 seconds, and 90 seconds, respectively. Other than that, a SiO₂ film was formed on the substrate in the same manner as in Example 37. Physical property values of the SiO₂ films obtained in the Examples are indicated in Table 7.

### Examples 43 to 45

In Examples 43 to 45, tetramethylguanidine gas (manufactured by Sigma. Aldrich Co., LLC, purity: 99%) was used as the second catalyst gas in the reaction gas supply process (C). In addition, the supply time (pulse time) when the mixture gas including the H₂O gas and the N₂ gas and the mixture gas including die tetramethylguanidine gas and the N₂ gas were simultaneously supplied to the treatment container 11 was set to 6 seconds, 12 seconds, and 30 seconds, respectively, Other than that, a SiO₂ film was formed on the substrate in the same manner as in Example 37. Physical property values of the SiO₂ films obtained in the Examples are indicated in Table 7.

### (Result 7)

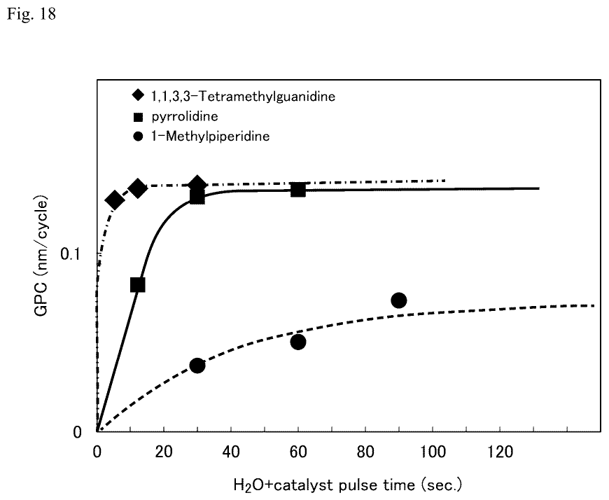

As shown in FIG. 18, in the case of Examples 37 to 39 in which a pyrrolidine gas having a pKa value of 11.3 was used as the second catalyst gas supplied together with the reaction gas, the film formation rate of the SiO₂ film was increased to 0.13 nm/cycle. In addition, also in the case of Examples 43 to 45 in which 1,1,3,3-tetramethylguanidine gas having a pKa value of 13.7 was used as the second catalyst gas, the film formation rate of the SiO₂ film was 0.13 to 0.14 nm/cycle. On the other hand, in the case of Examples 40 to 42 in which 1-methylpiperidine gas having a pKa value of 10.1 was used as the second catalyst gas, the film formation rate of the SiO₂ film was 0.04 to 0.08 nm/cycle. From these results, it was confirmed that the use of a catalyst having a large pKa value as the second catalyst gas makes it possible to increase the film formation rate and improve the film formation efficiency. Note that FIG. 18 is a graph illustrating a relationship between the supply time (pulse time) of a reaction gas and the film formation rate of a SiO₂ film.

TABLE 7

| | Source gas supply process | | | | Reaction gas supply process | | |
|---|---|---|---|---|---|---|---|
| | | | Temperature | Pressure in | | | Temperature |
| | | First | of treatment | treatment | | Second | of treatment |
| | Source | catalyst | container | container | Reaction | catalyst | container |
| | gas | gas | (° C.) | (kPa) | gas | gas | (° C.) |
| Example 37 | Si(NMe₂)(OMe)₃ | — | 80 | 0.13 to | H₂O | Pyrrolidine | 80 |
| | | | | 0.27 | | | |
| Example 38 | Si(NMe₂)(OMe)₃ | — | 80 | 0.13 to | H₂O | Pyrrolidine | 80 |
| | | | | 0.27 | | | |
| Example 39 | Si(NMe₂)(OMe)₃ | — | 80 | 0.13 to | H₂O | Pyrrolidine | 80 |
| | | | | 0.27 | | | |
| Example 40 | Si(NMe₂)(OMe)₃ | — | 80 | 0.13 to | H₂O | 1-methylpiperidine | 80 |
| | | | | 0.27 | | | |
| Example 41 | Si(NMe₂)(OMe)₃ | — | 80 | 0.13 to | H₂O | 1-methylpiperidine | 80 |
| | | | | 0.27 | | | |
| Example 42 | Si(NMe₂)(OMe)₃ | — | 80 | 0.13 to | H₂O | 1-methylpiperidine | 80 |
| | | | | 0.27 | | | |
| Example 43 | Si(NMe₂)(OMe)₃ | — | 80 | 0.13 to | H₂O | 1,1,3,3- | 80 |
| | | | | 0.27 | | tetramethylguanidine | |
| Example 44 | Si(NMe₂)(OMe)₃ | — | 80 | 0.13 to | H₂O | 1,1,3,3- | 80 |
| | | | | 0.27 | | tetramethylguanidine | |
| Example 45 | Si(NMe₂)(OMe)₃ | — | 80 | 0.13 to | H₂O | 1,1,3,3- | 80 |
| | | | | 0.27 | | tetramethylguanidine | |

| | Reaction gas supply process | | | | | | |
|---|---|---|---|---|---|---|---|
| | Pressure in | | | | | | Film |
| | treatment | Supply | Number | Film | Film | Surface | formation |
| | container | time | of | density | thickness | roughness | rate |
| | (kPa) | (seconds) | cycles | (g/cm²) | (nm) | (nm) | (nm/cycle) |
| Example 37 | 5.33 to | 12 | 80 | 2.0 | 6.6 | 0.4 | 0.08 |
| | 6.67 | | | | | | |
| Example 38 | 5.33 to | 30 | 80 | 2.2 | 10.7 | 0.2 | 0.13 |
| | 6.67 | | | | | | |
| Example 39 | 5.33 to | 60 | 80 | 2.1 | 10.7 | 0.3 | 0.13 |
| | 6.67 | | | | | | |
| Example 40 | 5.33 to | 30 | 80 | 1.9 | 2.9 | 0.4 | 0.04 |
| | 6.67 | | | | | | |
| Example 41 | 5.33 to | 60 | 80 | 2.0 | 4.0 | 0.5 | 0.05 |
| | 6.67 | | | | | | |
| Example 42 | 5.33 to | 90 | 80 | 2.1 | 6.0 | 0.4 | 0.08 |
| | 6.67 | | | | | | |
| Example 43 | 5.33 to | 6 | 80 | 2.1 | 10.5 | 0.2 | 0.13 |
| | 6.67 | | | | | | |
| Example 44 | 5.33 to | 12 | 80 | 2.1 | 11.0 | 0.3 | 0.14 |
| | 6.67 | | | | | | |
| Example 45 | 5.33 to | 30 | 80 | 2.1 | 11.2 | 0.3 | 0.14 |
| | 6.67 | | | | | | |

### DESCRIPTION OF REFERENCE SIGNS

1: Film forming device
11: Treatment container
12: Source gas supply portion
13: First catalyst gas supply portion
14: Second catalyst gas supply portion
15: Reaction gas supply portion
17A to 17D: Carrier gas supply path
21: Source gas supply path
22: First catalyst gas supply path
23: Second catalyst gas supply path
24: Reaction gas supply path
25: Purge gas supply path
26: Discharge path
27: APC valve

1. A film forming method for forming a film on a workpiece, the method comprising:
a process (A) of providing the workpiece in a treatment container;
a source gas supply process (B) of supplying a source gas into the treatment container to adsorb the source gas onto the workpiece, and then purging an inside of the treatment container with a first purge gas; and
a reaction gas supply process (C) of supplying a reaction gas into the treatment container after the source gas supply process (B) to oxidize the source gas adsorbed on the workpiece, and then purging the inside of the treatment container with a second purge gas,
wherein the supply of the source gas in the source gas supply process (B) is one of:
a process (b1) of supplying a first catalyst gas into the treatment container together with the source gas;
a process (b2) of supplying a first catalyst gas into the treatment container, then performing purging with a third purge gas, and then supplying the source gas; or
a process (b3) of supplying only the source gas into the treatment container,
the supply of the reaction gas in the reaction gas supply process (C) is one of:
a process (c1) of supplying a second catalyst gas into the treatment container together with the reaction gas;
a process (c2) of supplying a second catalyst gas into the treatment container before supplying the reaction gas, and then performing purging with a fourth purge gas; or
a process (c3) of supplying only the reaction gas into the treatment container,
the method does not comprise the reaction gas supply process (C) being the process (c3) when the source gas supply process (B) is the process (b3), and
the first catalyst gas and the second catalyst gas are a same or different types of non-aromatic amine gas.

2. The film forming method according to claim 1, wherein an acid dissociation constant pKa of the non-aromatic amine gas at 25° C. is in a range of 9.5 or more and 14 or less.

3. The film forming method according to claim 1, wherein the non-aromatic amine gas is at least one type selected from a group consisting of a pyrrolidine gas, a piperidine gas, a 1,1,3,3-tetramethylguanidine gas, a 1-methylpiperidine gas, and a gas of a derivative thereof.

4. The film forming method according to claim 1, wherein the source gas is a group 4 element gas of a periodic table having no halogen ligand and/or a silicon gas having no halogen ligand.

5. The film forming method according to claim 4, wherein the source gas is represented by a general formula Aₘ-M-B₍₄₋ₘ₎ (where A and B are each independently any one type selected from a group consisting of an R¹O group, an R²R³N group, a CpR⁴ group, a C_{q}H_{2q}N group (q=4 or 5), and a hydrogen atom; in addition, R¹, R², R³, and R⁴ are each independently a CᵣH₂₊₁ group (r≥0); M is Ti, Zr, Hf, or Si; Cp is a cyclopentadienyl ligand; and 0≤m≤4).

6. The film forming method according to claim 5, wherein the source gas is at least one type of gas selected from a group consisting of Si(OMe)₄, Si(NMe₂)(OMe)₃, Si(NMe₂)₂(OMe)₂, Si(NMe₂)₃(OMe), Si(NMe₂)(OEt)₃, Si(NMe₂)₂(OEt)₂, Si(NMe₂)₃(OEt), Si(NEt₂)(OMe)₃, Si(NEt₂)(OEt)₃, SiH(NMe₂)₃, SiH₂(NEt₂)₂, SiH₂(NHt-Bu)₂, Si(pyrrolidine)(OMe)₃, Si(pyrrolidine)₂(OMe)₂, and Si(pyrrolidine)₃(OMe).

7. The film forming method according to claim 1 wherein the reaction gas is an oxidant gas having an oxygen atom.

8. The film forming method according to claim 7, wherein the oxidant gas is at least one type of gas selected from a group consisting of water, hydrogen peroxide water, formic acid, and aldehyde.

9. The film forming method according to claim 1, wherein
the supply of the source gas and/or the first catalyst gas in the source gas supply process is performed such that a pressure in the treatment container is in a range of 13 Pa or more and 40000 Pa or less, and
the supply of the reaction gas and/or the second catalyst gas in the reaction gas supply process is performed such that the pressure in the treatment container is in a range of 13 Pa or more and 40000 Pa or less.

10. The film forming method according to claim 1, wherein a temperature in the treatment container in the source gas supply process and/or the reaction gas supply process is 200° C. or lower.
